(19) United States
(12) Patent Application Publication
(10) Pub. No.: US 2025/0303514 A1
(43) Pub. Date: Oct. 2, 2025

(54) INFORMATION PROCESSING DEVICE, SUBSTRATE POLISHING DEVICE, INFERENCE DEVICE, MACHINE LEARNING DEVICE, INFORMATION PROCESSING METHOD, INFERENCE METHOD, AND MACHINE LEARNING METHOD

(71) Applicant: EBARA CORPORATION, Tokyo (JP)

(72) Inventors: Seungho YUN, Tokyo (JP); Masayoshi ITO, Tokyo (JP)

(21) Appl. No.: 19/090,177

(22) Filed: Mar. 25, 2025

(30) Foreign Application Priority Data
Mar. 29, 2024 (JP) 2024-055695

(51) Int. Cl. B24B 37/015

(52) U.S. Cl. CPC B24B 37/015

(57) ABSTRACT

Provided is an information processing device including an information acquisition section that acquires substrate polishing information including measured temperature distribution information indicating a measured value of a temperature distribution of a polishing surface when a polishing process for polishing a substrate with the polishing surface of a polishing pad is performed by a substrate polishing device and device state information indicating a device state of the substrate polishing device, and an information generation section that inputs the substrate polishing information acquired by the information acquisition section into a learning model to generate polishing surface temperature control information indicating a control amount of a polishing surface temperature adjustment section when a polishing process is performed by the substrate polishing device. The learning model is a trained model that has learned a correlation between the substrate polishing information and the polishing surface temperature control information by machine learning.

### TECHNICAL FIELD

The disclosure relates to an information processing device, an inference device, a machine learning device, an information processing method, an inference method, and a machine learning method.

### BACKGROUND

As one of the substrate processing devices that perform various processes on substrates such as semiconductor wafers, a substrate polishing device that performs a chemical mechanical polishing (CMP) process is known. In the chemical mechanical polishing process, for example, while rotating a polishing table section having a polishing pad, a polishing liquid (slurry) is supplied to the polishing pad from a polishing fluid supply nozzle. In this state, the substrate is pressed against the polishing pad by a polishing head section called a top ring, whereby the substrate is chemically and mechanically polished.

In this case, the processing quality of the substrate polished by the chemical mechanical polishing process depends not only on the pressing load of the substrate against the polishing pad, but also on the temperature distribution on the polishing surface of the polishing pad. This is because the chemical action of the polishing liquid on the substrate depends on temperature.

Therefore, when performing chemical mechanical polishing process, a temperature adjustment device is used to adjust the temperature distribution of the polishing pad in order to maintain the temperature distribution of the polishing surface of the polishing pad at an appropriate target temperature (see, for example, JP 2001-179613 A).

### SUMMARY

The temperature adjustment device for the polishing pad disclosed in JP 2001-179613 A determines the control amount of the heating device or cooling device so that the polishing pad has a predetermined temperature distribution. However, the temperature distribution of the polishing pad varies in a complex manner due to various device states that the substrate polishing device can take when performing chemical mechanical polishing process. Thus, it was difficult to accurately determine the control amount of the temperature adjustment device by analyzing all behaviors and factors.

In view of the above problems, an object of the disclosure is to provide an information processing device, an inference device, a machine learning device, an information processing method, an inference method, and a machine learning method that can improve the processing quality of a substrate by chemical mechanical polishing process.

In order to achieve the above object, an information processing device according to one aspect of the disclosure includes: an information acquisition section that acquires substrate polishing information including measured temperature distribution information indicating a measured value of a temperature distribution of a polishing surface when a polishing process for polishing a substrate with the polishing surface of a polishing pad is performed by a substrate polishing device, and device state information indicating a device state of the substrate polishing device; and an information generation section that inputs the substrate polishing information acquired by the information acquisition section into a learning model, thereby generating polishing surface temperature control information indicating a control amount of a polishing surface temperature adjustment section that adjusts the temperature distribution of the polishing surface when the polishing process is performed by the substrate polishing device having the device state indicated by the device state information included in the substrate polishing information for the polishing surface having the temperature distribution indicated by the measured temperature distribution information included in the substrate polishing information, wherein the learning model is a trained model that has learned a correlation between the substrate polishing information and the polishing surface temperature control information by machine learning.

According to an information processing device according to one aspect of the disclosure, by inputting the substrate polishing information including the measured temperature distribution information indicating the measured value of the temperature distribution of the polishing surface and the device state information indicating the device state of the substrate polishing device to a learning model, the polishing surface temperature control information for the substrate polishing information is generated. Therefore, the temperature distribution of the polishing surface is appropriately adjusted based on the polishing surface temperature control information, so that the processing quality of the substrate by the chemical mechanical polishing process can be improved.

Other problems, configurations, and effects will become apparent from the Description of the Embodiments described below.

### BRIEF DESCRIPTION OF DRAWINGS

FIG. 1 is an overall configuration diagram showing an example of a substrate polishing system 1.

FIG. 2 is a schematic configuration diagram showing an example of a substrate polishing device 2.

FIG. 3 is a schematic diagram showing an example of a polishing head section 202.

FIG. 4 is a schematic diagram showing an example of a polishing surface heating section 206.

FIG. 5 is a schematic diagram showing an example of a polishing surface cooling section 207.

FIG. 6 is a block diagram showing an example of a substrate polishing device 2 (information processing device 6) according to the first embodiment.

FIG. 7 is a hardware configuration diagram showing an example of a computer 900.

FIG. 8 is a data configuration diagram showing an example of a database 30.

FIG. 9 is a block diagram showing an example of a machine learning device 4 according to the first embodiment.

FIG. 10 is a schematic diagram showing an example of learning data 11A according to the first embodiment and the relationship with reinforcement learning.

FIG. 11 is a diagram showing an example of a learning model 10A according to the first embodiment.

FIG. 12 is a flowchart showing an example of a machine learning method by the machine learning device 4 according to the first embodiment.

FIG. 13 is a functional explanatory diagram showing an example of a substrate polishing device 2 (information processing device 6) according to the first embodiment.

FIG. 14 is a flowchart showing an example of an information processing method by the substrate polishing device 2 (information processing device 6) according to the first embodiment.

FIG. 15 is a block diagram showing an example of a machine learning device 4a according to the second embodiment.

FIG. 16 is a diagram showing an example of a learning model 10B and learning data 11B according to the second embodiment.

FIG. 17 is a flowchart showing an example of a machine learning method by the machine learning device 4a according to the second embodiment.

FIG. 18 is a block diagram showing an example of a substrate polishing device 2a (information processing device 6a) according to the second embodiment.

FIG. 19 is a functional explanatory diagram showing an example of a substrate polishing device 2a (information processing device 6a) according to the second embodiment.

FIG. 20 is a flowchart showing an example of an information processing method by the substrate polishing device 2a (information processing device 6a) according to the second embodiment.

### DESCRIPTION OF EMBODIMENTS

Hereinafter, an embodiment for carrying out the disclosure will be described with reference to the drawings. In the following, the scope necessary for the description to achieve the object of the disclosure will be shown in a schematic manner, focusing mainly on the scope necessary for the description of the relevant part of the disclosure, and the parts for which description is omitted will be based on known techniques.

### First Embodiment

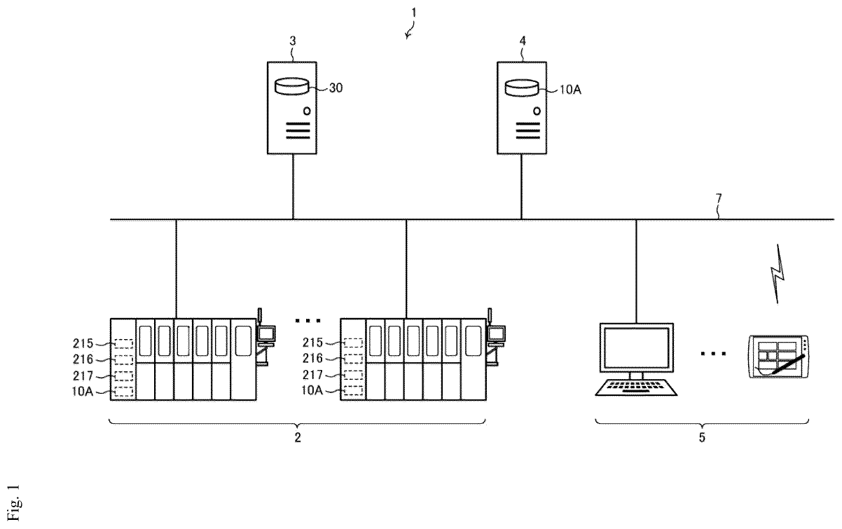

FIG. 1 is an overall configuration diagram showing an example of a substrate polishing system 1. The substrate polishing system 1 according to this embodiment functions as a system for managing a chemical mechanical polishing process (hereinafter referred to as a “polishing process”) for polishing the surface of a substrate (hereinafter referred to as a “wafer”) W such as a semiconductor wafer to a flat surface.

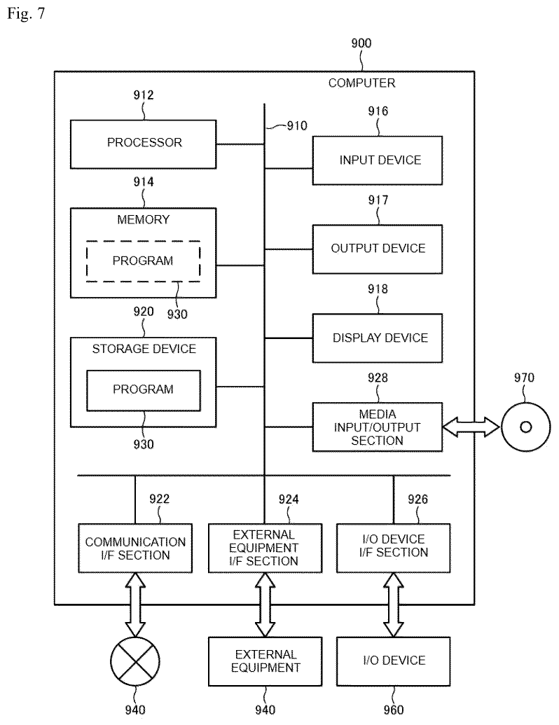

The substrate polishing system 1 mainly includes a substrate polishing device 2, a database device 3, a machine learning device 4, and a user terminal device 5. Each of the devices 2 to 5 is, for example, configured as a general-purpose or dedicated computer (see FIG. 7 described later), and is connected to a wired or wireless network 7 so that various pieces of data can be transmitted and received each other. The number of devices 2 to 5 and the connection configuration of the network 7 are not limited to the example in FIG. 1 and may be changed as appropriate.

The substrate polishing device 2 is a device that performs a polishing process to polish a wafer W. At that time, the substrate polishing device 2 controls the operation of the substrate polishing device 2 using a trained learning model 10A (trained model) generated by the machine learning device 4 while referring to device setting information 215 consisting of a plurality of device parameters and substrate recipe information 216 that defines the polishing conditions of the polishing process, etc.

In addition, the substrate polishing device 2 accumulates various pieces of information as operation history information 217 in response to performing the polishing process, and transmits the operation history information 217 to the database device 3. The operation history information 217 includes, for example, device state information indicating the device state of the substrate polishing device 2 when the polishing process was performed, event information detected by the substrate polishing device 2, operation information of the user (operator, production manager, maintenance manager, and the like) on the substrate polishing device 2, and the like.

The database device 3 includes a database 30 that accumulates the operation history information 217 transmitted from each substrate polishing device 2. In addition to the operation history information 217 transmitted from each substrate polishing device 2, the database 30 may accumulate information on a test of a polishing process performed using a dummy wafer. The test of the polishing process may be performed by the substrate polishing device 2, by a polishing test device capable of reproducing the polishing process, or by a polishing simulation device capable of simulating the polishing process. The database 30 may also store the device setting information 215 and substrate recipe information 216.

The machine learning device 4, for example, acquires a part of the information accumulated in the database 30 as learning data 11A, and generates a learning model 10A used in the substrate polishing device 2 by machine learning. The trained learning model 10A (trained model) is provided to the substrate polishing device 2 via the network 7, a recording medium, or the like.

The user terminal device 5 is a terminal device used by a user, and may be a stationary device or a portable device. The user terminal device 5 accepts various input operations via a display screen such as an application program or a web browser, and displays various pieces of information (e.g., event notification, device setting information 215, substrate recipe information 216, operation history information 217, and the like) via the display screen. Some of the information may be editable via the user terminal device 5.

The learning model 10A according to this embodiment employs reinforcement learning as a machine learning technique. The machine learning device 4 is installed, for example, in an assembly factory or evaluation facility for the substrate polishing device 2, and executes a learning phase of reinforcement learning. The substrate polishing device 2 is installed, for example, in a manufacturing factory for wafers W, etc., and executes an inference phase of reinforcement learning using the learning model 10A that has been trained by the machine learning device 4, and further executes a learning phase of reinforcement learning to adapt to an individual environment such as the manufacturing factory for wafers W.

### Substrate Polishing Device 2

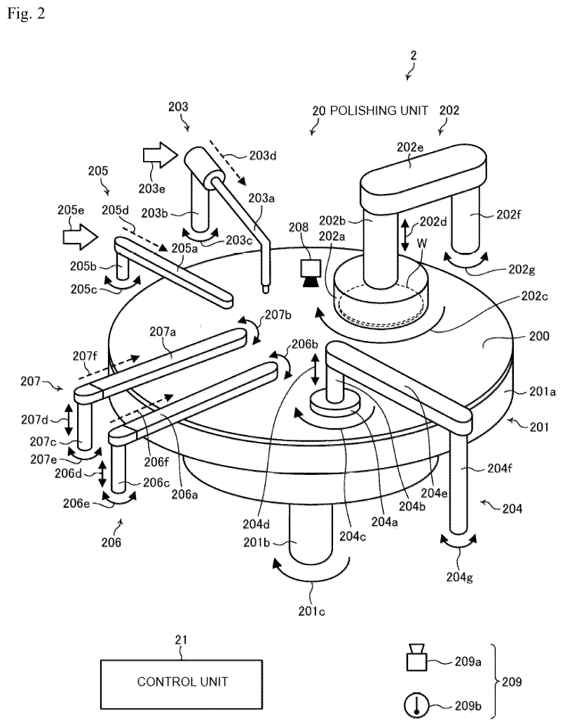

FIG. 2 is a schematic configuration diagram showing an example of the substrate polishing device 2. The substrate polishing device 2 includes a polishing unit 20 that performs polishing process on the wafer W, and a control unit 21 that controls the operation of the substrate polishing device 2. The substrate polishing device 2 may include at least one polishing unit 20. In addition to the polishing unit 20, the substrate polishing device 2 may also include, for example, a substrate transport unit that transports the wafer W, a cleaning unit that cleans the wafer W, and the like.

The polishing unit 20 includes a polishing table section 201 that rotatably supports a polishing pad 200 having a polishing surface, a polishing head section 202 (top ring) that presses a wafer W against the polishing surface of the polishing pad 200 to polish the wafer W, a polishing fluid supply section 203 that supplies a polishing fluid to the polishing pad 200, a dressing section 204 (dresser) that performs dressing (conditioning) of the polishing surface of the polishing pad 200, a cleaning fluid injection section 205 (atomizer) that injects a cleaning fluid onto the polishing pad 200, a polishing surface heating section 206 and a polishing surface cooling section 207 that function as a polishing surface temperature adjustment section that adjusts the temperature distribution of the polishing surface of the polishing pad 200, a polishing surface temperature measuring section 208 that measures the temperature distribution of the polishing surface of the polishing pad 200, and a polishing unit measuring section 209 that measures the state of the wafer W and the state of the processing environment in which the polishing process is performed.

The polishing table section 201 includes a polishing table 201a to which the polishing pad 200 is replaceably attached, a polishing table shaft 201b that supports the polishing table 201a, and a rotational movement mechanism section 201c that rotationally drives the polishing table 201a around the axis of the polishing table shaft 201b.

The polishing head section 202 includes a polishing head 202a that holds the wafer W, a polishing head shaft 202b that supports the polishing head 202a, a rotational movement mechanism section 202c that rotationally drives the polishing head 202a around the axis of the polishing head shaft 202b, a vertical movement mechanism section 202d that moves the polishing head 202a in the vertical direction, a support arm 202e that supports the polishing head shaft 202b, a support shaft 202f that supports the support arm 202e, and a swinging movement mechanism section 202g that rotationally (swingingly) moves the polishing head 202a around the support shaft 202f as the center of rotation.

The polishing fluid supply section 203 includes a polishing fluid supply nozzle 203a capable of supplying a polishing fluid, a support shaft 203b supporting the polishing fluid supply nozzle 203a, a swinging movement mechanism section 203c that rotationally (swingingly) moves the polishing fluid supply nozzle 203a around the support shaft 203b as the center of rotation, a flow rate adjustment section 203d that adjusts the flow rate of the polishing fluid, and a temperature adjustment mechanism section 203e that adjusts the temperature of the polishing fluid. The polishing fluid is a polishing liquid (slurry) or pure water, and may further include a chemical solution or may be a polishing liquid to which a dispersant has been added.

The dressing section 204 includes a dressing head 204a to which a dressing pad (not shown) is replaceably attached, a dressing shaft 204b that supports the dressing head 204a, a rotational movement mechanism section 204c that rotationally drives the dressing head 204a around the axis of the dressing shaft 204b, a vertical movement mechanism section 204d that moves the dressing head 204a in the vertical direction, a support arm 204e that supports the dressing shaft 204b, a support shaft 204f that supports the support arm 204e, and a swinging movement mechanism section 204g that rotationally (swingingly) moves the dressing head 204a around the support shaft 204f as the center of rotation.

The cleaning fluid injection section 205 includes a cleaning fluid injection nozzle 205a capable of injecting the cleaning fluid, a support shaft 205b that supports the cleaning fluid injection nozzle 205a, a swinging movement mechanism section 205c that rotationally (swingingly) moves the cleaning fluid injection nozzle 205a around the support shaft 205b as the center of rotation, a flow rate adjustment section 205d that adjusts the flow rate of the cleaning fluid, and a temperature adjustment mechanism section 205e that adjusts the temperature of the polishing fluid. The cleaning fluid is a mixed fluid of a liquid (e.g., pure water) and a gas (e.g., nitrogen gas) or a liquid (e.g., pure water).

The polishing surface heating section 206 includes a heating fluid injection nozzle 206a capable of injecting a heating fluid, a rotational movement mechanism section 206b that rotationally drives the heating fluid injection nozzle 206a around the axis of the heating fluid injection nozzle 206a, a support shaft 206c that supports the heating fluid injection nozzle 206a, a vertical movement mechanism section 206d that moves the heating fluid injection nozzle 206a in the vertical direction, a swinging movement mechanism section 206e that rotationally (swingingly) moves the heating fluid injection nozzle 206a around the support shaft 206c as the center of rotation, and a heating fluid supply mechanism 206f that supplies the heating fluid. The heating fluid may be a high-temperature gas (e.g., air, an inert gas such as nitrogen, argon, and the like) or high-temperature steam.

The polishing surface cooling section 207 includes a cooling fluid injection nozzle 207a capable of injecting a cooling fluid, a rotational movement mechanism section 207b that rotationally drives the cooling fluid injection nozzle 207a around the axis of the cooling fluid injection nozzle 207a, a support shaft 207c that supports the cooling fluid injection nozzle 207a, a vertical movement mechanism section 207d that moves the cooling fluid injection nozzle 207a in the vertical direction, a swinging movement mechanism section 207e that rotationally (swingingly) moves the cooling fluid injection nozzle 207a around the support shaft 207c as the center of rotation, and a cooling fluid supply mechanism 207f that supplies the cooling fluid. The cooling fluid may be a gas at room temperature (e.g., air, an inert gas such as nitrogen, argon, or the like) or a gas cooled to a set temperature lower than room temperature. The moving mechanism section of the polishing surface heating section 206 and the polishing surface cooling section 207 may be common. In that case, the polishing surface heating section 206 and the polishing surface cooling section 207 are moved by the common moving mechanism section.

The polishing surface temperature measuring section 208 measures the temperature distribution of the polishing surface of the polishing pad 200 in a non-contact or contact manner, and outputs measured temperature distribution information indicating the measured value. The measured temperature distribution information is, for example, a record of the distribution of temperature according to the radial position of the polishing pad 200. The measured temperature distribution information may be a record of the distribution of temperature according to the radial position of the polishing pad 200 for each circumferential direction of the polishing pad 200.

The polishing surface temperature measuring section 208 is configured with a temperature sensor such as a thermograph, a thermopile, and an infrared camera. The polishing surface temperature measuring section 208 may be configured with a plurality of temperature sensors such as an infrared radiation thermometer and a thermocouple thermometer. The polishing surface temperature measuring section 208 may be configured by combining a plurality of types of temperature sensors.

The polishing unit measuring section 209 includes a substrate measuring section 209a that measures the state of the wafer W, and an environment measuring section 209b that measures the state of the processing environment in which the polishing process is performed.

The substrate measuring section 209a measures the state of the wafer W before the polishing process, the state of the wafer W during the polishing process, and the state of the wafer W after the polishing process. The substrate measuring section 209a is configured with sensors that measure, for example, the film thickness of the wafer W, the temperature distribution on the surface of the wafer W, and the like, as the state of the wafer W, but are not limited to these.

The environment measuring section 209b is configured with sensors that measure, for example, the temperature, humidity, air pressure, and the like, of the processing environment, as the state of the processing environment, but are not limited to these.

Note that, in FIG. 2, the specific configurations of the rotational movement mechanism sections 201c, 202c, 204c, 206b, 207b, the vertical movement mechanism sections 202d, 204d, 206d, 207d, and the swinging movement mechanism sections 202g, 203c, 204g, 205c, 206e, 207e are omitted. However, for example, they are configured by appropriately combining modules for generating driving force such as motors and fluid pressure cylinders, driving force transmission mechanisms such as linear guides, ball screws, gears, belts, couplings, and bearings, and sensors such as linear sensors, encoder sensors, limit sensors, and torque sensors. In FIG. 2, the specific configurations of the flow rate adjustment sections 203d and 205d are omitted, but for example, they are configured by appropriately combining modules for adjusting fluid such as pumps, valves, and regulators, and sensors such as flow rate sensors, pressure sensors, and liquid level sensors. In FIG. 2, the specific configurations of the temperature adjustment mechanism sections 203e and 205e are omitted, but for example, they are configured by appropriately combining temperature adjustment modules (contact type or non-contact type) such as heaters and heat exchangers, and sensors such as temperature sensors.

### Polishing Head Section 202

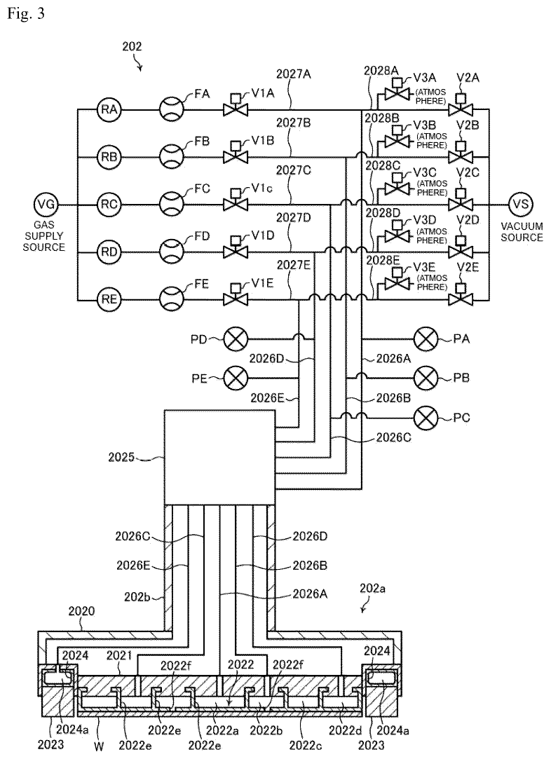

FIG. 3 is a schematic diagram showing an example of the polishing head section 202. The polishing head 202a includes a top ring body 2020 attached to the polishing head shaft 202b, a roughly disk-shaped carrier 2021 housed in the top ring body 2020, a membrane 2022 arranged below the carrier 2021 to press the wafer W against the polishing pad 200, a roughly annular retainer ring 2023 arranged on the outer periphery of the carrier 2021 and the membrane 2022 to directly press the polishing pad 200, and a retainer ring airbag 2024 arranged between the top ring body 2020 and the retainer ring 2023 to press the retainer ring 2023 against the polishing pad 200.

The membrane 2022 is made of an elastic film and has a plurality of concentric partition walls 2022e therein, thereby providing first to fourth membrane pressure chambers 2022a to 2022d arranged concentrically from the center to the outer periphery of the top ring body 2020. The membrane 2022 also has a plurality of holes 2022f for sucking the wafer W on its lower surface, and functions as a substrate holding surface for holding the wafer W. The retainer ring airbag 2024 is made of an elastic film and has a retainer ring pressure chamber 2024a therein. The configuration of the polishing head 202a may be changed as appropriate, and may include a pressure chamber for pressing the entire carrier 2021. The number and shape of the membrane pressure chambers of the membrane 2022 may be changed as appropriate, and the number and arrangement of the suction holes 2022f may be changed as appropriate. The membrane 2022 may not have the suction holes 2022f.

First to fourth flow paths 2026A to 2026D are connected to the first to fourth membrane pressure chambers 2022a to 2022d, respectively, and a fifth flow path 2026E is connected to the retainer ring pressure chamber 2024a. The first to fifth flow paths 2026A to 2026E are connected to the outside via a rotary joint 2025 provided on the polishing head shaft 202b, and are branched into first branch flow paths 2027A to 2027E and second branch flow paths 2028A to 2028E, respectively. Pressure sensors PA to PE are installed in the first to fifth flow paths 2026A to 2026E, respectively. The first branch flow paths 2027A to 2027E are connected to a gas supply source GS of a pressure fluid (air, nitrogen, and the like) via valves VIA to VIE, flow rate sensors FA to FE, and pressure regulators RA to RE. The second branch flow paths 2028A to 2028E are connected to a vacuum source VS via valves V2A to V2E, respectively, and are configured to be able to communicate with the atmosphere via valves V3A to V3E.

The wafer W is held by suction on the lower surface of the polishing head 202a and moved to a predetermined polishing position on the polishing table section 201, and then polished by being pressed by the polishing head 202a against the polishing surface of the polishing pad 200 to which the polishing fluid is supplied from the polishing fluid supply section 203. At this time, the polishing head 202a independently controls the pressure regulators RA to RE to adjust the pressing force of pressing the wafer W against the polishing pad 200 by the pressure fluid supplied to the first to fourth membrane pressure chambers 2022a to 2022d for each region of the wafer W, and adjust the pressing force of pressing the retainer ring 2023 against the polishing pad 200 by the pressure fluid supplied to the retainer ring pressure chamber 2024a. The pressures of the pressure fluids supplied to the first to fourth membrane pressure chambers 2022a to 2022d and the retainer ring pressure chamber 2024a are measured by the pressure sensors PA to PE, respectively, and the flow rates of the pressure gases are measured by the flow rate sensors FA to FE, respectively.

### Polishing Surface Heating Section 206

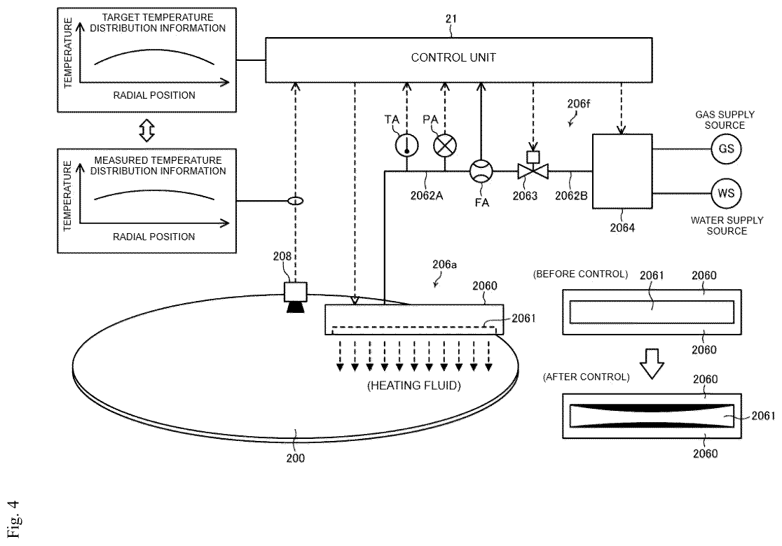

FIG. 4 is a schematic diagram showing an example of the polishing surface heating section 206. The heating fluid injection nozzle 206a includes a nozzle body 2060 attached to the support shaft 206c, and a heating fluid injection port 2061 for injecting a heating fluid toward the polishing surface of the polishing pad 200. The nozzle body 2060 is formed in a cylindrical shape, and has a heating fluid flow path (not shown) therein. As shown in FIG. 4, the heating fluid injection port 2061 may be a long hole formed along the longitudinal direction of the nozzle body 2060, or a plurality of small holes formed to be arranged in the longitudinal direction of the nozzle body 2060. The heating fluid injection port 2061 may be provided with an opening degree adjustment mechanism that adjusts the opening degree of the heating fluid injection port 2061 using a piezoelectric element, a shutter member, or the like.

The heating fluid supply mechanism 206f includes a flow rate control valve 2063 connected to the heating fluid injection nozzle 206a via a first flow path 2062A, and a heating fluid generator 2064 connected to the flow rate control valve 2063 via a second flow path 2062B. As shown in FIG. 4, a gas supply source GS and a water supply source WS are connected to the heating fluid generator 2064. When the heating fluid is high-temperature steam, the gas supply source GS may be omitted, and when the heating fluid is high-temperature gas, the water supply source WS may be omitted. A flow rate sensor FA, a pressure sensor PA, and a temperature sensor TA are installed in the first flow path 2062A.

### Polishing Surface Cooling Section 207

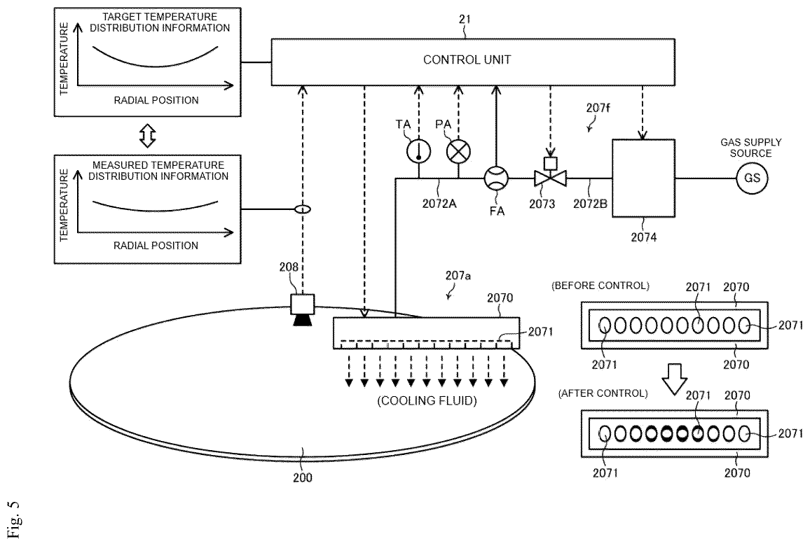

FIG. 5 is a schematic diagram showing an example of the polishing surface cooling section 207. The cooling fluid injection nozzle 207a includes a nozzle body 2070 attached to a support shaft 207c, and a cooling fluid injection port 2071 for injecting a cooling fluid toward the polishing surface of the polishing pad 200. The nozzle body 2070 is formed in a cylindrical shape, and has a flow path (not shown) for the cooling fluid therein. The cooling fluid injection port 2071 may be a long hole formed along the longitudinal direction of the nozzle body 2070, or may be a plurality of small holes formed to be arranged in the longitudinal direction of the nozzle body 2070 as shown in FIG. 5. The cooling fluid injection port 2071 may be provided with an opening degree adjustment mechanism for adjusting the opening degree of the cooling fluid injection port 2071 using a piezoelectric element, a shutter member, or the like.

The cooling fluid supply mechanism 207f includes a flow rate control valve 2073 connected to the cooling fluid injection nozzle 207a via a first flow path 2072A, and a cooling fluid generator 2074 connected to the flow rate control valve 2073 via a second flow path 2072B. A gas supply source GS is connected to the cooling fluid generator 2074. A flow rate sensor FB, a pressure sensor PB, and a temperature sensor TA are installed in the first flow path 2072A. If the cooling fluid is a gas at room temperature, the cooling fluid generator 2074 may be omitted.

The heating fluid supply mechanism 206f and the cooling fluid supply mechanism 207f are controlled by the control unit 21 so that the measured temperature distribution information indicating the measured value of the temperature distribution of the polishing surface by the polishing surface temperature measuring section 208 satisfies the target temperature distribution information indicating the target value of the temperature distribution of the polishing surface.

The target temperature distribution information of the polishing pad 200 is included in, for example, the device setting information 215 or the substrate recipe information 216, and is referred to by the control unit 21. The target temperature distribution information is defined in the same way as the measured temperature distribution information, and is, for example, a record of the temperature distribution according to the radial position of the polishing pad 200. The target temperature distribution information may be a constant value or a variable value from the start to the end of the polishing process.

When the heating fluid supply mechanism 206f and the cooling fluid supply mechanism 207f are controlled by the control unit 21, for example, the opening degree of the heating fluid injection port 2061 and the opening degree of the cooling fluid injection port 2071 are changed from the pre-control state to the post-control state as shown in FIG. 4 and FIG. 5 so that the difference between the measured temperature distribution information and the target temperature distribution information becomes small. In addition to the above opening degree, the flow rate, pressure, temperature, and supply position of the heating fluid, and the flow rate, pressure, temperature, and supply position of the cooling fluid are used as the control amounts for the polishing surface heating section 206 and the polishing surface cooling section 207, and these may be combined as appropriate.

Note that the configurations of the polishing surface heating section 206 and the polishing surface cooling section 207 are not limited to the above example. For example, the shape and arrangement of the heating fluid injection port 2061 and the cooling fluid injection port 2071 may be changed as appropriate. In addition, the number of the heating fluid injection port 2061 and the cooling fluid injection port 2071 may be one or more. When there is a plurality of heating fluid injection ports 2061 and cooling fluid injection ports 2071, the flow rate, pressure, temperature, and supply position of the heating fluid or cooling fluid may be controlled for each heating fluid injection port 2061 or each cooling fluid injection port 2071, or the opening degree of the heating fluid injection port 2061 or cooling fluid injection port 2071 may be controlled for each heating fluid injection port 2061 or each cooling fluid injection port 2071.

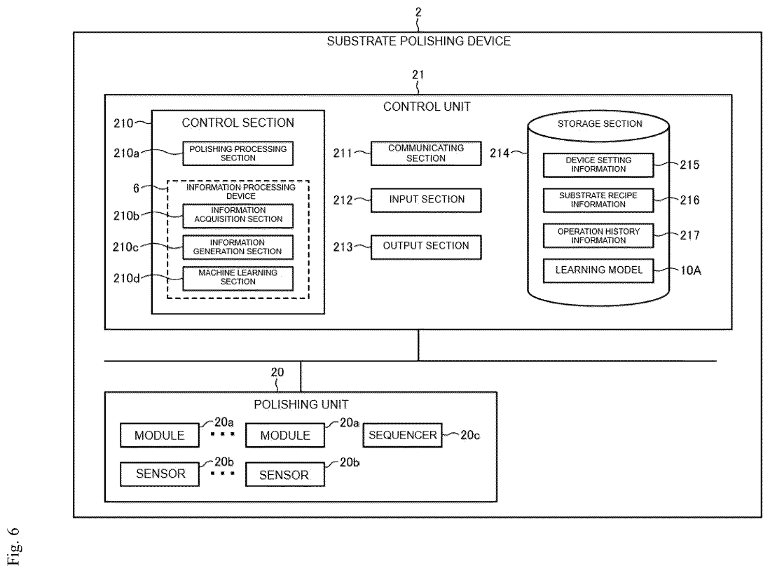

FIG. 6 is a block diagram showing an example of the substrate polishing device 2 (information processing device 6) according to the first embodiment. The control unit 21 is electrically connected to each of the parts 201 to 209 of the polishing unit 20, and functions as a control section that controls the polishing unit 20 in an integrated manner.

The polishing unit 20 includes a plurality of modules 20a to be controlled, which are arranged in each of the parts 201 to 209 of the polishing unit 20, a plurality of sensors 20b arranged in the modules 20a to detect data (detected values and measured values) required for controlling each module 20a, and a sequencer 20c that controls the operation of each module 20a based on the detected values and measured values from each sensor 20b.

The sensors 20b of the polishing unit 20 include, for example, sensors for detecting the rotation speed and rotation torque of the polishing table section 201, sensors for detecting the rotation speed, rotation torque, swing torque, and height of the polishing head section 202, sensors for detecting the swing position of the polishing head section 202, which can be converted into the polishing position of the polishing head section 202, sensors for detecting the lifting torque of the polishing head section 202, which can be converted into the pressing load of the polishing head section 202, and the pressure (positive pressure and negative pressure) of the first to fourth membrane pressure chambers 2022a to 2022d and the retainer ring pressure chamber 2024a, sensors for detecting the flow rate of the pressure fluid supplied to the first to fourth membrane pressure chambers 2022a to 2022d and the retainer ring pressure chamber 2024a, sensors for detecting the surface roughness of the polishing pad 200, sensors for detecting the flow rate and temperature of the polishing fluid supplied from the polishing fluid supply section 203, sensors for detecting the swing position of the polishing fluid supply section 203, which can be converted into a dripping position of the polishing fluid, sensors for detecting the rotation speed, rotation torque, swing torque and height of the dressing section 204, sensors for detecting the swing position of the dressing section 204, which can be converted into a dressing position of the dressing section 204, sensors for detecting the lifting torque of the dressing section 204, which can be converted into a pressing load of the dressing section 204, sensors for detecting the flow rate, pressure, and temperature of the cleaning fluid supplied from the cleaning fluid injection section 205, sensors for detecting the swing position of the cleaning fluid injection section 205, which can be converted into a dripping position of the cleaning fluid, sensors for detecting the flow rate, pressure, and temperature of the heating fluid supplied from the polishing surface heating section 206, sensors for detecting the rotation angle, height, swing position, and opening degree of the polishing surface heating section 206, which can be converted into the supply position of the heating fluid, sensors for detecting the opening degree of the heating fluid injection port 2061 of the polishing surface heating section 206, sensors for detecting the flow rate, pressure, and temperature of the cooling fluid supplied from the polishing surface cooling section 207, sensors for detecting the rotation angle, height, and swing position of the polishing surface cooling section 207, which can be converted into the supply position of the cooling fluid, sensors for detecting the opening degree of the cooling fluid injection port 2071 of the polishing surface cooling section 207, sensors of the polishing surface temperature measuring section 208, and sensors of the polishing unit measuring section 209.

The control unit 21 includes a control section 210, a communicating section 211, an input section 212, an output section 213, and a storage section 214. The control unit 21 is configured as, for example, a general-purpose or dedicated computer (see FIG. 7 described later).

The communicating section 211 is connected to the network 7 and functions as a communication interface for transmitting and receiving various pieces of data. The input section 212 accepts various input operations, and the output section 213 functions as a user interface by outputting various pieces of information via a display screen, a signal tower light, and a buzzer sound.

The storage section 214 stores various programs (operating system (OS), application programs, web browser, and the like) and data (device setting information 215, substrate recipe information 216, operation history information 217, learning model 10A, and the like) used in the operation of the substrate polishing device 2.

The control section 210 functions as a polishing processing section 210a, an information acquisition section 210b, an information generation section 210c, and a machine learning section 210d.

The polishing processing section 210a performs a polishing process on the wafer W by acquiring detected values and measured values from a plurality of sensors 20b (hereinafter referred to as a “sensor group”) via the sequencer 20c and coordinating the operation of a plurality of modules 20a (hereinafter referred to as a “module group”). The polishing processing section 210a also stores the detected values and measured values from each sensor 20b as operation history information 217 in the storage section 214.

The information acquisition section 210b and the information generation section 210c execute the inference phase of reinforcement learning using the learning model 10A when the polishing process is performed. The machine learning section 210d executes the learning phase of reinforcement learning for the learning model 10A when the polishing process is performed. The information acquisition section 210b, the information generation section 210c, and the machine learning section 210d constitute the information processing device 6. Details of the information processing device 6 will be described later.

### Hardware Configuration of Each Device

FIG. 7 is a hardware configuration diagram showing an example of a computer 900. Each of the substrate polishing device 2 (particularly the control unit 21), the database device 3, the machine learning device 4, and the user terminal device 5 is configured as a general-purpose or dedicated computer 900.

As shown in FIG. 7, the computer 900 includes, as its main components, a bus 910, a processor 912, a memory 914, an input device 916, an output device 917, a display device 918, a storage device 920, a communication I/F (interface) section 922, an external equipment I/F section 924, an I/O (input/output) equipment I/F section 926, and a media input/output section 928. The above components may be omitted as appropriate depending on the purpose for which the computer 900 is used.

The processor 912 is configured with one or more arithmetic processing devices (CPU (Central Processing Unit), MPU (Micro-Processing Unit), DSP (Digital Signal Processor), GPU (Graphics Processing Unit), NPU (Neural Processing Unit), and the like) and operates as a control section that integrates the entire computer 900. The memory 914 stores various pieces of data and programs 930 and is configured with, for example, a volatile memory (DRAM, SRAM, and the like) that functions as a main memory, a non-volatile memory (ROM), a flash memory, and the like.

The input device 916 is configured with, for example, a keyboard, a mouse, a numeric keypad, an electronic pen, and the like and functions as an input section. The output device 917 is configured with, for example, a sound (audio) output device, a vibration device, and the like, and functions as an output section. The display device 918 is configured with, for example, a liquid crystal display, an organic EL display, electronic paper, a projector, and the like, and functions as an output section. The input device 916 and the display device 918 may be integrally configured, such as a touch panel display. The storage device 920 is configured with, for example, a HDD, an SSD, and the like, and functions as a storage section. The storage device 920 stores various pieces of data required for the execution of the operating system and the program 930.

The communication I/F section 922 is connected to a network 940 (which may be the same as the network 7 in FIG. 1) such as the Internet or an intranet by wire or wirelessly, and functions as a communicating section that transmits and receives data to and from other computers according to a predetermined communication standard. The external equipment I/F section 924 is connected to an external equipment 950 such as a camera, a printer, a scanner, a reader/writer by wire or wirelessly, and functions as a communicating section that transmits and receives data to and from the external equipment 950 according to a predetermined communication standard. The I/O device I/F section 926 is connected to an I/O device 960 such as various sensors and actuators, and functions as a communicating section that transmits and receives various signals and data, such as detection signals from sensors and control signals to actuators, to and from the I/O device 960. The media input/output section 928 is configured with, for example, a drive device such as a DVD drive or a CD drive, a memory card slot, and a USB connector, and reads and writes data from and to a medium (non-transient storage medium) 970 such as a DVD, a CD, a memory card, or a USB memory.

In the computer 900 having the above configuration, the processor 912 calls up the program 930 stored in the storage device 920 into the memory 914, executes the program 930, and controls each part of the computer 900 via the bus 910. The program 930 may be stored in the memory 914 instead of the storage device 920. The program 930 may be recorded in the medium 970 in an installable file format or an executable file format, and provided to the computer 900 via the media input/output section 928. The program 930 may be provided to the computer 900 by downloading the same via the network 940 through the communication I/F section 922. In addition, the computer 900 may realize various functions realized by the processor 912 executing the program 930 with hardware such as an FPGA (Field-Programmable Gate Array) or an ASIC (Application Specific Integrated Circuit).

The computer 900 is configured with, for example, a stationary computer or a portable computer, and is an electronic equipment of any form. The computer 900 may be a client-type computer, a server-type computer, or a cloud-type computer, or may be, for example, an embedded computer called a control panel or a controller (including a microcomputer, a programmable logic controller, and a sequencer). The computer 900 may also be applied to devices other than the devices 2 to 5.

### Database 30

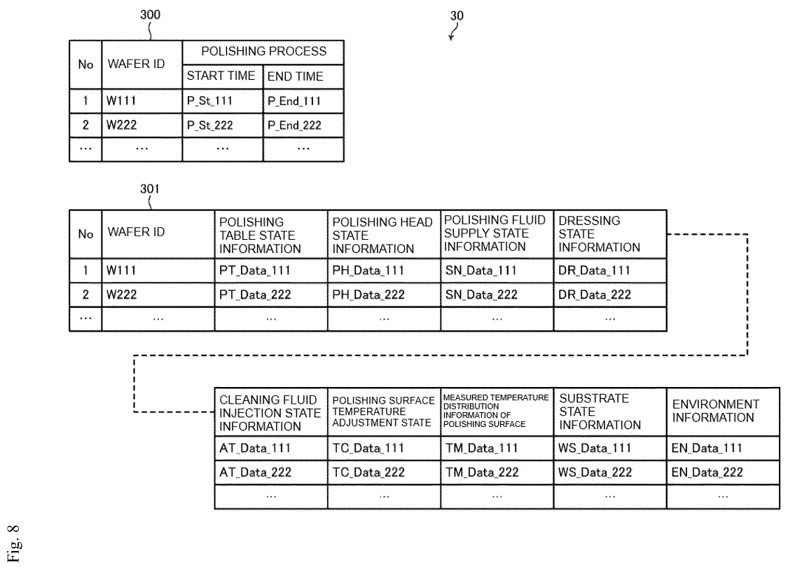

FIG. 8 is a data configuration diagram showing an example of the database 30. In the database 30, the operation history information 217 acquired when the polishing process on the wafer W is performed in the substrate polishing device 2 is classified and registered. The database 30 includes, for example, a wafer history table 300 for each wafer W and a polishing history table 301 for device state information during the polishing process. In addition to the above, the database 30 includes an event history table for event information and an operation history table for operation information, but detailed explanations are omitted.

In each record in the wafer history table 300, for example, a wafer ID for identifying the wafer W, a start time, an end time of the polishing process, and the like are registered.

In each record in the polishing history table 301, for example, a wafer ID, polishing table state information, polishing head state information, polishing fluid supply state information, dressing state information, cleaning fluid injection state information, polishing surface temperature adjustment state information, measured temperature distribution information, substrate state information, and environment information are registered.

The polishing table state information is information indicating the state of the polishing table section 201 during the polishing process. The polishing table state information is, for example, the detected value or measured value from each sensor sampled at a predetermined time interval by the sensor group of the polishing table section 201.

The polishing head state information is information indicating the state of the polishing head section 202 during the polishing process. The polishing head state information is, for example, the detected value or measured value from each sensor sampled at a predetermined time interval by the sensor group of the polishing head section 202.

The polishing fluid supply state information is information indicating the state of the polishing fluid supply section 203 during the polishing process. The polishing fluid supply state information is, for example, the detected value or measured value from each sensor sampled at a predetermined time interval by the sensor group of the polishing fluid supply section 203.

The dressing state information is information indicating the state of the dressing section 204 during the polishing process. The polishing fluid supply state information is, for example, the detected value or measured value from each sensor sampled at a predetermined time interval by the sensor group of the dressing section 204.

The cleaning fluid injection state information is information indicating the state of the cleaning fluid injection section 205 during the polishing process. The polishing fluid supply state information is, for example, the detected value or measured value from each sensor sampled at a predetermined time interval by the sensor group of the cleaning fluid injection section 205.

The polishing surface temperature adjustment state information is information indicating the state of the polishing surface heating section 206 and the polishing surface cooling section 207 that function as a polishing surface temperature adjustment section during the polishing process. The polishing surface temperature adjustment state information is, for example, the detected value or measured value from each sensor sampled at a predetermined time interval by the sensor group of the polishing surface heating section 206 and the polishing surface cooling section 207.

The measured temperature distribution information is information indicating the temperature distribution of the polishing surface of the polishing pad 200 during the polishing process. The measured temperature distribution information is, for example, measured values sampled at a predetermined time interval by the polishing surface temperature measuring section 208.

The substrate state information is information indicating the state of the wafer W. The substrate state information is, for example, the detected values and measured values from each sensor sampled at a predetermined time interval by the substrate measuring section 209a.

The environment information is information indicating the state of the processing environment in which the polishing process is performed. The environment information is, for example, the detected values and measured values from each sensor sampled at a predetermined time interval by the environment measuring section 209b.

By referring to the polishing history table 301, time-series data of the detected values and measured values from each sensor can be extracted as the device state information of the substrate polishing device 2 when the polishing process is performed on the wafer W identified by the wafer ID. Note that, instead of the detected values and measured values from each sensor, command values to each module may be registered in the polishing history table 301. At that time, the command values for each module are set based on the device setting information 215 and the substrate recipe information 216, but the setting values set in the device setting information 215 and the substrate recipe information 216 may be registered as device state information.

### Machine Learning Device 4

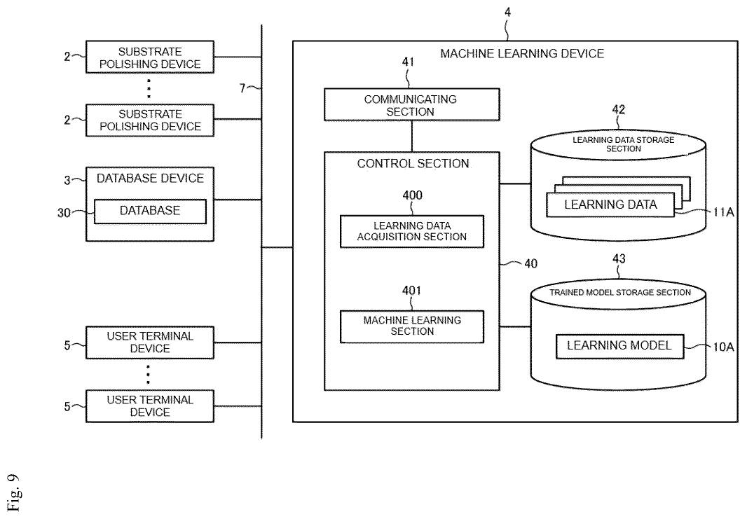

FIG. 9 is a block diagram showing an example of the machine learning device 4 according to the first embodiment. The machine learning device 4 includes a control section 40, a communicating section 41, a learning data storage section 42, and a trained model storage section 43.

The control section 40 functions as a learning data acquisition section 400 and a machine learning section 401. The communicating section 41 is connected to an external device (e.g., the substrate polishing device 2, the database device 3, the user terminal device 5, a polishing test device (not shown), a polishing simulation device (not shown), and the like) via the network 7, and functions as a communication interface for transmitting and receiving various pieces of data.

The learning data acquisition section 400 is connected to an external device via the communicating section 41 and the network 7, and acquires learning data 11A that is at least composed of substrate polishing information as input data. The learning data 11A is acquired, for example, by referring to the database 30. In this embodiment, the learning data 11A is data used for reinforcement learning.

The learning data storage section 42 is a database that stores a plurality of sets of learning data 11A acquired by the learning data acquisition section 400. Note that the specific configuration of the database that constitutes the learning data storage section 42 may be designed as appropriate.

The machine learning section 401 performs machine learning using a plurality of sets of learning data 11A. That is, the machine learning section 401 inputs a plurality of sets of learning data 11A to the learning model 10A, and generates a trained learning model 10A by causing the learning model 10A to learn the correlation between the substrate polishing information included as input data in the learning data 11A and the polishing surface temperature control information through reinforcement learning. The machine learning section 401 may perform a predetermined pre-processing on the input data (substrate polishing information) input to the learning model 10A, or may perform a predetermined post-processing on the output data (polishing surface temperature control information) output from the learning model 10A.

The trained model storage section 43 is a database that stores the trained learning model 10A (specifically, the adjusted weight parameter group) generated by the machine learning section 401. The trained learning model 10A stored in the trained model storage section 43 is provided to a real system (e.g., the substrate polishing device 2) via the network 7, a recording medium, or the like. In FIG. 9, the learning data storage section 42 and the trained model storage section 43 are shown as separate storage sections, but they may be configured as a single storage section.

The number of learning models 10A stored in the trained model storage section 43 is not limited to one. For example, a plurality of learning models with different conditions, such as machine learning techniques, types of wafers W (size, thickness, film type, and the like), differences in the configuration of the polishing units 20, types of membranes 2022, types of retainer rings 2023, types of polishing pads 200, types of polishing fluids, types of cleaning fluids, types of heating fluids, types of cooling fluids, types of data included in substrate polishing information, and types of data included in polishing surface temperature control information, may be stored and used selectively or in parallel. In that case, the learning data storage section 42 may store a plurality of types of learning data having data configurations corresponding to a plurality of learning models with different conditions.

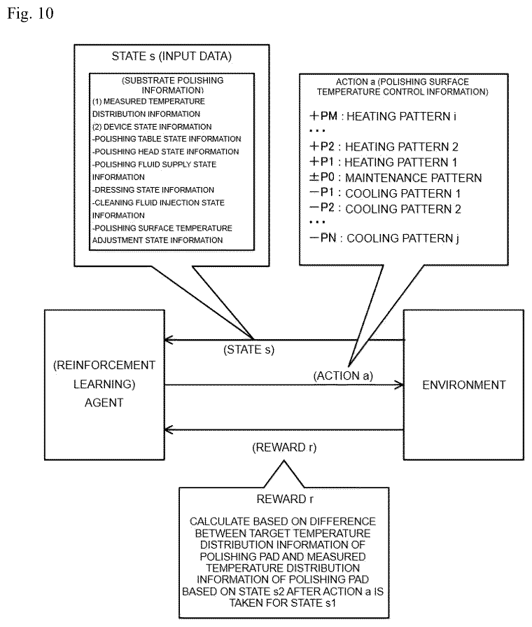

FIG. 10 is a schematic diagram showing the relationship between an example of learning data 11A according to the first embodiment and reinforcement learning. The machine learning section 401 functions as an agent of reinforcement learning. In the basic mechanism of reinforcement learning, the agent observes the state of the environment under a predetermined condition, and selects an action according to a predetermined policy for the observed state. Then, when the state of the environment changes due to the selected action, the agent receives a reward according to the change in state, and evaluates the value of the selected action. As a series of such processes, the observation of the state, the selection of the action, and the evaluation of the value are repeated, whereby the learning model 10A learns a policy for selecting an action that can maximize the reward.

When the reinforcement learning by the machine learning section 401 is made to correspond to the basic mechanism of reinforcement learning described above, the environment corresponds to the substrate polishing device 2 performing the polishing process so that the measured temperature distribution information of the polishing pad 200 satisfies the target temperature distribution information of the polishing pad 200.

The state s is represented by substrate polishing information as information corresponding to the input data. The substrate polishing information includes the measured temperature distribution information of the polishing pad 200 and the device state information of the substrate polishing device 2. The substrate polishing information may be time-series data from the past to the present.

The measured temperature distribution information of the polishing pad 200 is the temperature distribution of the polishing surface of the polishing pad 200 measured by the polishing surface temperature measuring section 208. In this case, the measured temperature distribution information of the polishing pad 200 may be a processed value obtained by performing a normalization process on the measured value measured by the polishing surface temperature measuring section 208. The normalization process is a process for normalizing the temperature to a predetermined range (e.g., 0 to 1).

The device state information of the substrate polishing device 2 includes polishing surface temperature adjustment state information indicating the state of the polishing surface heating section 206 and the polishing surface cooling section 207 that function as a polishing surface temperature adjustment section.

The polishing surface temperature adjustment state information includes at least one of the flow rate, pressure, temperature, and supply position of the heating fluid, and the opening degree of the heating fluid injection port 2061 of the polishing surface heating section 206 as the current polishing surface heating state, and at least one of the flow rate, pressure, temperature, and supply position of the cooling fluid, and the opening degree of the cooling fluid injection port 2071 of the polishing surface cooling section 207 as the current polishing surface cooling state. In this embodiment, it has been described that the substrate polishing device 2 includes the polishing surface heating section 206 and the polishing surface cooling section 207 as the polishing surface temperature adjustment sections, and the polishing surface temperature adjustment state information includes both the polishing surface heating state and the polishing surface cooling state. However, if the substrate polishing device 2 includes either the polishing surface heating section 206 or the polishing surface cooling section 207, the polishing surface temperature adjustment state information may include either the corresponding polishing surface heating state or the polishing surface cooling state.

The device state information of the substrate polishing device 2 may include other information as long as it affects the temperature distribution of the polishing surface of the polishing pad 200.

For example, as shown in FIG. 10, the device state information of the substrate polishing device 2 may further include at least one of polishing table state information indicating the state of the polishing table section 201, polishing head state information indicating the state of the polishing head section 202, polishing fluid supply state information indicating the state of the polishing fluid supply section 203, dressing state information indicating the state of the dressing section 204, cleaning fluid injection state information indicating the state of the cleaning fluid injection section 205, and substrate state information indicating the state of the wafer W.

The polishing table state information includes at least one of the rotation speed and rotation torque of the polishing table section 201, the type and surface roughness of the polishing pad 200, and the polishing time during which the polishing process is performed by the polishing pad 200.

The polishing head state information includes at least one of the rotation speed, rotation torque, polishing position, and pressing load of the polishing head section 202.

The polishing fluid supply state information includes at least one of the flow rate, temperature, dripping position, and type of the polishing fluid. Note that, if the polishing fluid is a plurality of types of polishing fluid (e.g., polishing liquid, pure water, chemical liquid, dispersant, and the like), it is sufficient that the polishing fluid supply state information includes at least one of the flow rate of each type, the dripping position of each type, and the temperature of each type. For example, if the polishing fluid is a polishing liquid and pure water, it is sufficient that the polishing fluid supply state information includes at least one of the flow rate of the polishing liquid, the dripping position of the polishing liquid, the temperature of the polishing liquid, the flow rate of the pure water, the dripping position of the pure water, and the temperature of the pure water.

The dressing state information includes at least one of the rotation speed, rotation torque, dressing position, pressing load, type of dressing pad, and dressing time during which dressing was performed by the dressing pad of the dressing section 204.

The cleaning fluid injection state information includes at least one of the flow rate, temperature, dripping position, and type of the cleaning fluid.

The substrate state information includes at least one of the film thickness of the wafer W, the type of the film of the wafer W, and the temperature distribution on the surface of the wafer W.

The device state information of the substrate polishing device 2 may further include environment information indicating the state of the processing environment. The environment information includes at least one of the temperature, humidity, and air pressure of the processing environment.

The action a is a candidate for polishing surface temperature control information indicating the control amount when the temperature distribution of the polishing pad 200 is adjusted by the polishing surface heating section 206 and the polishing surface cooling section 207 that function as a polishing surface temperature adjustment section.

The polishing surface temperature control information is a control amount for the polishing surface heating section 206 and the polishing surface cooling section 207. Specifically, the polishing surface temperature control information includes at least one of the flow rate, pressure, temperature, and supply position of the heating fluid, and the opening degree of the heating fluid injection port 2061 of the polishing surface heating section 206 when the polishing surface of the polishing pad 200 is heated by the polishing surface heating section 206, and at least one of the flow rate, pressure, temperature, and supply position of the cooling fluid, and the opening degree of the cooling fluid injection port 2071 of the polishing surface cooling section 207 when the polishing surface of the polishing pad 200 is cooled by the polishing surface cooling section 207. In this embodiment, it has been described that the substrate polishing device 2 is provided with the polishing surface heating section 206 and the polishing surface cooling section 207 as the polishing surface temperature adjustment section, and the polishing surface temperature control information includes information for both the polishing surface heating section 206 and the polishing surface cooling section 207. However, when the substrate polishing device 2 is provided with either the polishing surface heating section 206 or the polishing surface cooling section 207, the polishing surface temperature control information may include any of the corresponding information.

The control amount for the polishing surface heating section 206 and the polishing surface cooling section 207 may be expressed as an absolute amount or a change amount relative to the control amount before control, or may be expressed as a step value or a continuous value. In addition, the control amount for the polishing surface heating section 206 and the polishing surface cooling section 207 may be expressed as a control pattern that arbitrarily combines the above parameters (flow rate, pressure, temperature, and supply position of the heating fluid, opening degree of the heating fluid injection port 2061, flow rate, pressure, temperature, and supply position of the cooling fluid, and opening degree of the cooling fluid injection port 2071). In this embodiment, as shown in FIG. 10, the case will be described where action a is a candidate for a plurality of control patterns consisting of a plurality of heating patterns (+P1, +P2, . . . , +Pj), a maintenance pattern (±P0), and a plurality of cooling patterns (−P1, −P2, . . . , −Pj).

The reward r is calculated based on the difference between the target temperature distribution information of the polishing pad 200 and the measured temperature distribution information of the polishing pad 200 based on the state s2 after action a is taken for the state s1. At that time, the reward r is calculated so that it becomes larger as the difference between the target temperature distribution information of the polishing pad 200 and the measured temperature distribution information becomes smaller.

The measured temperature distribution information of the polishing pad 200 based on the state s2 is the temperature distribution of the polishing pad 200 after the action a is taken for the state s1, that is, after the polishing surface heating section 206 and the polishing surface cooling section 207 adjust the temperature of the polishing pad 200 based on the control amount of the polishing surface heating section 206 and the polishing surface cooling section 207 indicated by the polishing surface temperature control information corresponding to the action a. The measured temperature distribution information of the polishing pad 200 may be a measured value measured by the polishing surface temperature measuring section 208, may be obtained based on the past operation history information 217 registered in the database 30, or may be estimated by performing a simulation by the polishing simulation device.

When reinforcement learning is adopted as machine learning, the learning data includes only input data corresponding to the state s. In other words, the learning data is configured not to include output data. The input data constituting the learning data according to this embodiment is substrate polishing information including the measured temperature distribution information of the polishing pad 200 and the device state information of the substrate polishing device 2, as shown in FIG. 10.

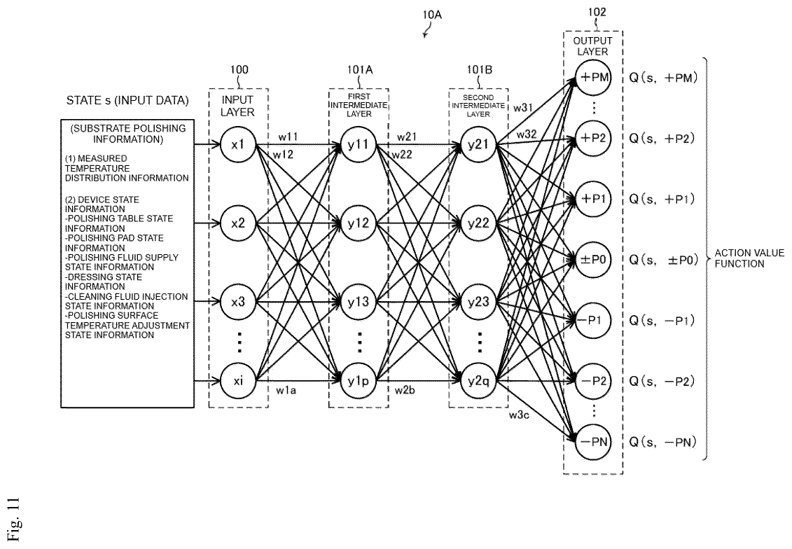

FIG. 11 is a diagram showing an example of the learning model 10A according to the first embodiment. In FIG. 11, the evaluation of taking a predetermined action a for the state s is performed using an action value function Q(s, a) of the Q-learning method.

The action value function Q(s, a) can be approximately calculated, for example, by a method called DQN (Deep Q-Network) using a neural network model in which the state s is an input variable and the action value function Q(s, aj) when each action aj (+PM, . . . , +P2, +P1, ±P0, −P1, −P2, . . . , −PN) is taken for the state s as an output variable. In this case, the machine learning section 401 updates the action value function Q(s, aj) by adjusting the weight wk of the neural network model so that an error function (e.g., TD error) including the reward r, learning rate α, and discount rate γ as variables is minimized, and the learning model 10A learns the correlation between the input data (state s) and the polishing surface temperature control information (action aj). Note that any method may be adopted as the reinforcement learning method, and in addition to the Q-learning method, for example, the SARSA method, the Monte Carlo method, and the like may be adopted.

The learning model 10A is configured as a neural network model shown in FIG. 11 in order to approximately calculate the action value function Q(s, aj). The neural network model shown in FIG. 11 is composed of i neurons (x1 to xi) in the input layer 100, p neurons (y11 to y1p) in the first intermediate layer 101A, q neurons (y21 to y2q) in the second intermediate layer 101B, and j (=M+N+1) neurons (+PM, . . . , +P2, +P1, ±P0, −P1, −P2, . . . , −PN) in the output layer.

Each neuron in the input layer 100 is associated with substrate polishing information as input data (state s) included in the learning data.

Each neuron in the output layer 102 is associated with each action value function Q(s, aj) when each action aj (+PM, . . . , +P2, +P1, ±P0, −P1, −P2, . . . , −PN) is taken for the state s, and each neuron in the output layer 102 outputs the value of the action value function Q(s, aj) for each action aj.

The first intermediate layer 101A and the second intermediate layer 101B are also called hidden layers, and the neural network may have a plurality of hidden layers in addition to the first intermediate layer 101A and the second intermediate layer 101B, or may have only the first intermediate layer 101A as the hidden layer. In addition, synapses that connect the neurons of each layer are laid between the input layer 100 and the first intermediate layer 101A, between the first intermediate layer 101A and the second intermediate layer 101B, and between the second intermediate layer 101B and the output layer 102, and a weight wk (k is a natural number) is associated with each synapse.

### Machine Learning Method

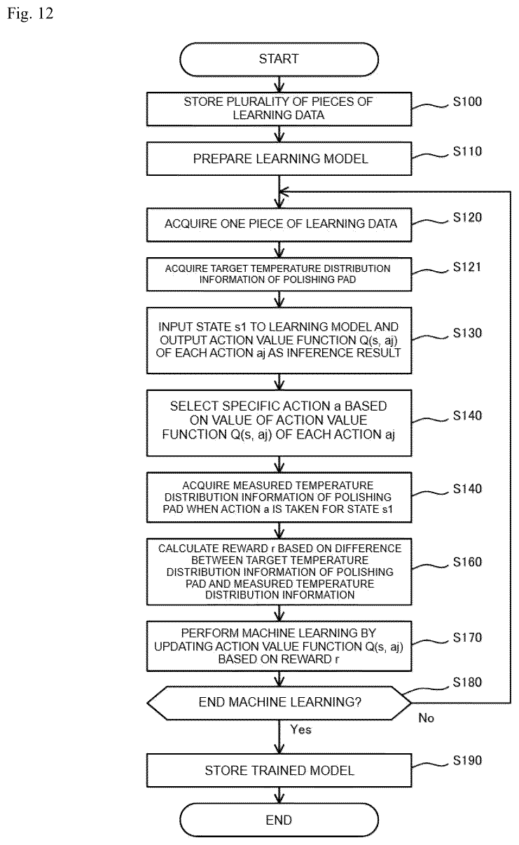

FIG. 12 is a flowchart showing an example of a machine learning method by the machine learning device 4 according to the first embodiment.

First, in step S100, the learning data acquisition section 400 prepares a desired number of pieces of learning data as a preparatory step for starting machine learning, and stores the prepared learning data in the learning data storage section 42. Several methods can be adopted for preparing the learning data.

Next, in step S110, the machine learning section 401 prepares a learning model 10A before learning in order to start machine learning. The learning model 10A before learning prepared here is configured as the neural network model exemplified in FIG. 11, and the weight wk of each synapse is set to an initial value.

Next, in step S120, the machine learning section 401 acquires, for example, one piece of learning data randomly from the plurality of sets of learning data stored in the learning data storage section 42.

Next, in step S121, the machine learning section 401 acquires target temperature distribution information of the polishing pad 200 for the input data included in the one learning data acquired in step S120.

Next, in step S130, the machine learning section 401 inputs the input data (state s1) included in the one learning data acquired in step S120 to the input layer 100 of the prepared learning model 10A before learning (or during learning). As a result, the value of each action aj (the value of the action value function Q(s, aj)) is output as an inference result from the output layer 102 of the learning model 10A.

Next, in step S140, the machine learning section 401 selects, for example, a specific action a corresponding to the maximum value based on the value of the action value function Q(s, aj) of each action aj output as the inference result from the output layer 102 in step S130. As a method for selecting a specific action a, for example, a greedy method, an &-greedy method, and the like may be adopted.

Next, in step S150, the machine learning section 401 acquires measured temperature distribution information of the polishing pad 200 when the action a selected in step S140 is taken for the state s1. That is, the machine learning section 401 acquires measured temperature distribution information of the polishing pad 200 after adjusting the temperature of the polishing pad 200 based on the control amount of the polishing surface heating section 206 and the polishing surface cooling section 207 indicated by the polishing surface temperature control information corresponding to the action a selected in step S140 for the polishing pad 200 having a temperature distribution indicated by the measured temperature distribution included in the substrate polishing information (state s1) as input data.

Next, in step S160, the machine learning section 401 calculates a reward r based on the difference between the target temperature distribution information of the polishing pad 200 acquired in step S121 and the measured temperature distribution information of the polishing pad 200 acquired in step S150.

Next, in step S170, the machine learning section 401 updates the action value function Q(s, aj) by adjusting the weight wk of the neural network model based on the reward r calculated in step S160 so that the error function is minimized. As a result, the machine learning section 401 causes the learning model 10A to learn the correlation between the substrate polishing information (state s) as input data and the polishing surface temperature control information (action aj). Note that the action value function Q(s, aj) does not have to be updated every time, and may be updated only when a predetermined condition is satisfied, for example.

Next, in step S180, the machine learning section 401 determines whether it is necessary to continue machine learning. As a result, if it is determined to continue (No in step S180), the process returns to step S120 and the process of steps S120 to S170 is performed on the learning model 10A being trained, and if it is determined to end the machine learning (Yes in step S180), the process proceeds to step S190.

Then, in step S190, the machine learning section 401 stores the trained learning model 10A generated by adjusting the weight wk associated with each synapse in the trained model storage section 43, and the series of machine learning methods shown in FIG. 12 ends. As the trained learning model 10A, for example, parameters representing the structure of a neural network and the adjusted weight wk are stored. In the machine learning method, step S100 corresponds to a training data acquisition process, steps S110 to S180 correspond to a machine learning process, and step S190 corresponds to a trained model storage process.

As described above, according to the machine learning device 4 and the machine learning method of this embodiment, it is possible to provide a learning model 10A that generates polishing surface temperature control information for substrate polishing information. Therefore, the temperature distribution of the polishing pad 200 is appropriately adjusted based on the polishing surface temperature control information generated by using the learning model 10A, so that the processing quality of the wafer W by the polishing process can be improved.

### (Substrate Polishing Device 2 and Information Processing Device 6)

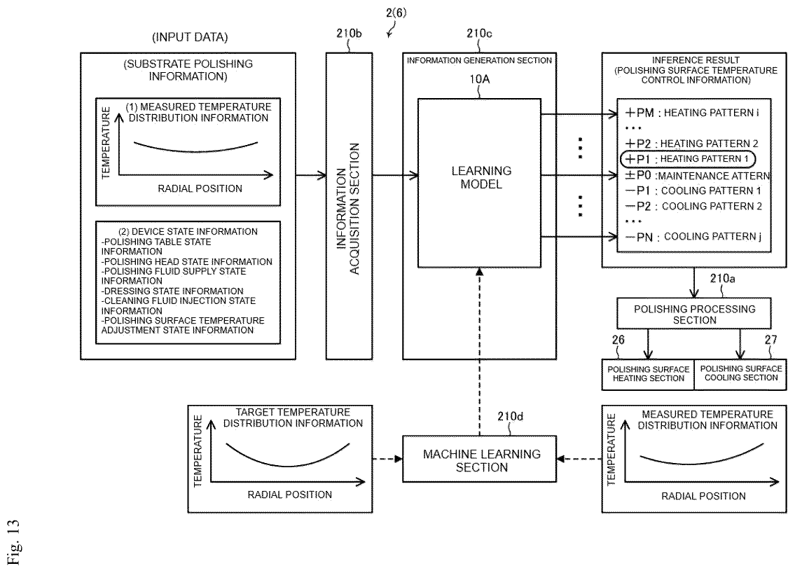

FIG. 13 is a functional explanatory diagram showing an example of the substrate polishing device 2 (information processing device 6) according to the first embodiment.

The information acquisition section 210b acquires substrate polishing information including measured temperature distribution information of the polishing pad 200 and device state information of the substrate polishing device 2. The measured temperature distribution information of the polishing pad 200 is acquired as a measured value from the polishing surface temperature measuring section 208. The device state information of the substrate polishing device 2 is acquired as a detected value or a measured value from a sensor group that the substrate polishing device 2 has. Note that the device state information may be acquired as a command value for the module group instead of the detected value or the measured value from the sensor group.

The information generation section 210c inputs the substrate polishing information acquired by the information acquisition section 210b as input data to the learning model 10A, and generates polishing surface temperature control information when polishing is performed by the substrate polishing device 2 having the device state indicated by the device state information included in the substrate polishing information against the polishing pad 200 having a temperature distribution indicated by the measured temperature distribution included in the substrate polishing information.

For example, the information generation section 210c selects, for example, a specific action a corresponding to the maximum value based on the value of the action value function Q(s, aj) of each action aj output as an inference result from the output layer 102 by inputting the substrate polishing information as input data to the learning model 10A, and generates polishing surface temperature control information corresponding to the specific action a as polishing surface temperature control information for the substrate polishing information of the input data.

In FIG. 13, a case is illustrated in which action a (+P1) is selected and heating pattern 1 corresponding to action a (+P1) is generated as polishing surface temperature control information. The polishing surface temperature control information generated by the information generation section 210c is output to the polishing processing section 210a, and the polishing surface heating section 206 and the polishing surface cooling section 207 are controlled by the polishing processing section 210a. That is, the polishing surface heating section 206 and the polishing surface cooling section 207 are controlled to execute the heating pattern 1 corresponding to the action a (+P1).

The machine learning section 210d performs machine learning of the learning model 10A through reinforcement learning while performing the polishing process on the wafer W, based on the operation history information 217 acquired at that time.

Specifically, the machine learning section 210d calculates the reward r based on the difference between the target temperature distribution information of the polishing pad 200 and the measured temperature distribution information when the polishing surface heating section 206 and the polishing surface cooling section 207 as the polishing surface temperature adjustment section are controlled based on the control amount indicated by the polishing surface temperature control information generated by the information generation section 210c. Then, based on the reward r, the machine learning section 210d causes the learning model 10A to learn the correlation between the input data (substrate polishing information) included in the learning data 11A and the polishing surface temperature control information through reinforcement learning. Note that if the difference between the target temperature distribution information and the measured temperature distribution information of the polishing pad 200 is smaller than a predetermined value, the machine learning of the learning model 10A may be omitted. In addition, the machine learning technique used by the machine learning section 210d is similar to that used by the machine learning section 401 of the machine learning device 4, and therefore a detailed description thereof will be omitted.

The number of learning models 10A stored in the storage section 214 is not limited to one. For example, a plurality of learning models with different conditions, such as machine learning techniques, types of wafer W (size, thickness, film type, and the like), differences in the configuration of the polishing units 20, types of membranes 2022, types of retainer rings 2023, types of polishing pads 200, types of polishing fluids, types of cleaning fluids, types of heating fluids, types of cooling fluids, types of data included in the substrate polishing information, types of data included in the polishing surface temperature control information, and the like, may be stored and used selectively or in parallel. The learning model 10A may also be written in a storage section of an external computer (for example, a server-type computer or a cloud-type computer), and in that case, the information generation section 210c and the machine learning section 210d may access the external computer.

### Information Processing Method

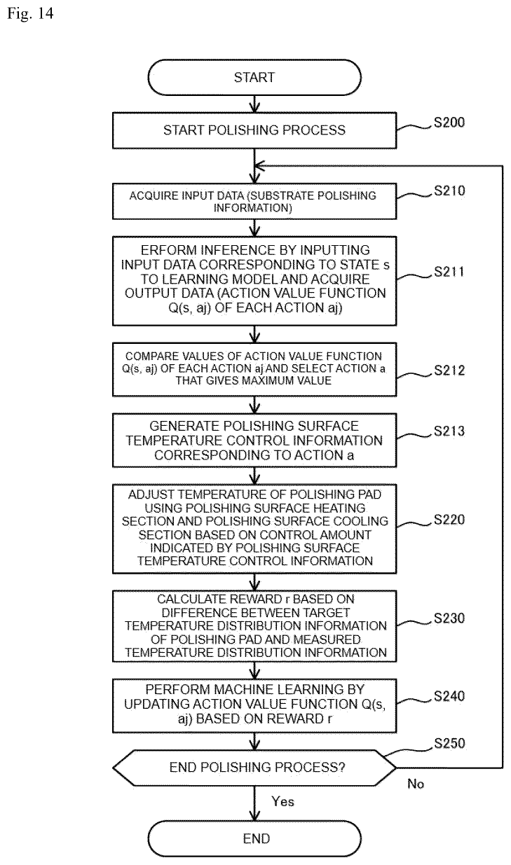

FIG. 14 is a flowchart showing an example of an information processing method by the substrate polishing device 2 (information processing device 6) according to the first embodiment. An example of the operation when the substrate polishing device 2 performs a polishing process on a specific wafer W will be described below.

First, in step S200, the polishing processing section 210a of the substrate polishing device 2 acquires detected values and measured values from the sensor group, and starts a polishing process for a specific wafer W by operating the module group in cooperation.

Next, in step S210, the information acquisition section 210b acquires substrate polishing information including the measured temperature distribution information of the polishing pad 200 and the device state information of the substrate polishing device 2 at a specific time point.

Next, in step S211, the information generation section 210c performs inference by inputting the substrate polishing information acquired in step S210 as input data to the learning model 10A, and acquires the values of the action value functions Q(s, +PM), . . . , Q(s, +P2), Q(s, +P1), Q(s, ±P0), Q(s, −P1), Q(s, −P2), . . . , Q(s, −PN) of each action a as output data output from the output layer 102 of the learning model 10A.

Next, in step S212, the information generation section 210c selects the action a that gives the maximum value among the values of the action value function Q(s, aj) of each action amn output from each neuron of the output layer 102 as output data, as an example of post-processing of reinforcement learning.

Next, in step S213, the output processing section 53 generates polishing surface temperature control information corresponding to the action a selected in step S211 (in the example of FIG. 13, acceleration pattern 1 corresponding to action a (+P1)) and outputs the polishing surface temperature control information to the polishing processing section 210a.

Next, in step S220, the polishing processing section 210a adjusts the temperature of the polishing pad 200 based on the control amount of the polishing surface heating section 206 and the polishing surface cooling section 207 indicated by the polishing surface temperature control information generated in step S213.

Next, in step S230, the machine learning section 210d calculates the reward r based on the difference between the target temperature distribution information of the polishing pad 200 and the measured temperature distribution information when the temperature of the polishing pad 200 is adjusted in step S220. The measured temperature distribution information here is measured when a predetermined sampling time interval has elapsed from the specific time point in step S210.

Next, in step S240, the machine learning section 210d updates the action value function Q(s, aj) based on the reward r calculated in step S230, so that the machine learning section 401 causes the learning model 10A to learn the correlation between the substrate polishing information (state s) as input data and the polishing surface temperature control information (action aj).

Next, in step S250, the polishing processing section 210a determines whether the polishing process has ended. As a result, if it is determined that the polishing process has not ended (No in step S250), the process returns to step S210 after the sampling time interval has elapsed, and the polishing process is continued. On the other hand, if it is determined that the polishing process has ended (Yes in step S250), the series of information processing methods shown in FIG. 14 ends. In the information processing method, steps S200 and S220 correspond to a polishing process step, step S210 corresponds to an information acquisition step, steps S211 to S213 correspond to an information generation step, and steps S230 and S240 correspond to a machine learning step.

As described above, according to the substrate polishing device 2 (information processing device 6) and information processing method of this embodiment, by inputting substrate polishing information into the learning model 10A, polishing surface temperature control information for the substrate polishing information is generated. Therefore, the temperature distribution of the polishing pad 200 is appropriately adjusted based on the polishing surface temperature control information, so that the processing quality of the wafer W by the polishing process can be improved.

In addition, since the machine learning of the learning model 10A is performed while the polishing process on the wafer W is being performed, the inference accuracy of the learning model 10A can be further improved in response to the environment in which the polishing process is actually performed.

### Second Embodiment

In the first embodiment, reinforcement learning is adopted as a machine learning technique for the learning model 10A, whereas the second embodiment differs from the first embodiment in that supervised learning is adopted. In the following, a substrate polishing device 2a (particularly an information processing device 6a) and a machine learning device 4a according to the second embodiment will be described, focusing on the differences from the first embodiment.

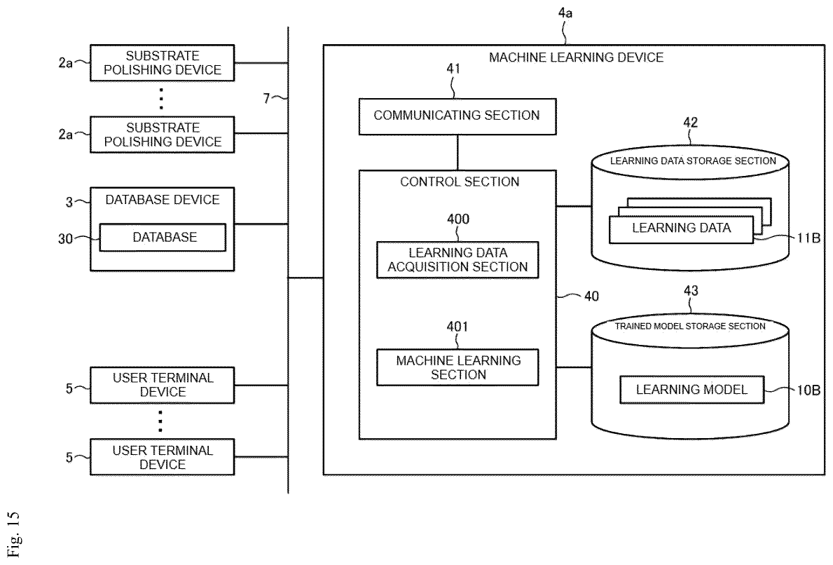

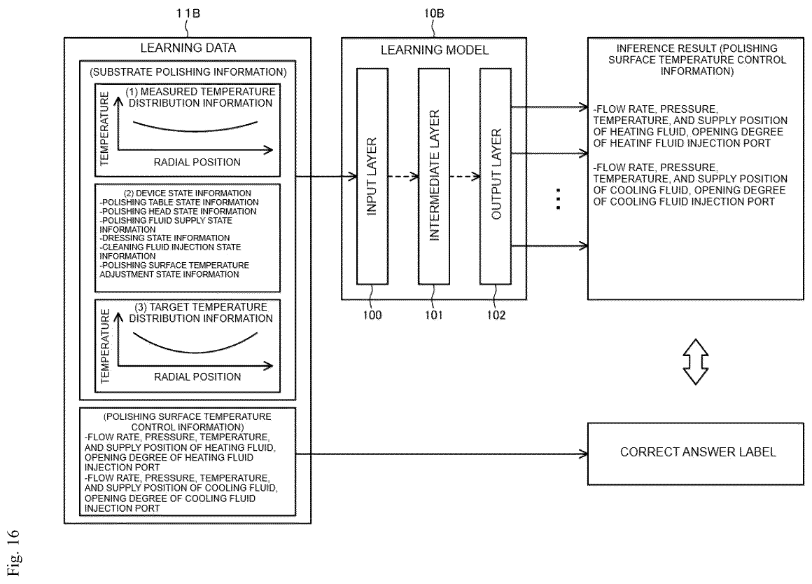

FIG. 15 is a block diagram showing an example of the machine learning device 4a according to the second embodiment. FIG. 16 is a diagram showing an example of the learning model 10B and the learning data 11B.

The learning data acquisition section 400 is connected to an external device via the communicating section 41 and the network 7, and acquires the learning data 11B consisting of substrate polishing information as input data and polishing surface temperature control information as output data. The learning data 11B is acquired, for example, by referring to the database 30. In this embodiment, the learning data 11B is data used as teacher data (training data), verification data, and test data in supervised learning. The polishing surface temperature control information is data used as a correct answer label in supervised learning.

The substrate polishing information includes measured temperature distribution information of the polishing pad 200 and device state information of the substrate polishing device 2, as in the first embodiment. The substrate polishing information may include target temperature distribution information of the polishing pad 200, as shown in FIG. 16.

The device state information of the substrate polishing device 2 may further include at least one of polishing table state information, polishing head state information, polishing fluid supply state information, and substrate state information, as in the first embodiment, or may include polishing surface temperature adjustment state information. The device state information of the substrate polishing device 2 may further include at least one of dressing state information, cleaning fluid injection state information, and environment information. Various pieces of data included in the substrate polishing information are the same as those in the first embodiment, and therefore will not be described.

The polishing surface temperature control information, as in the first embodiment, includes at least one of the flow rate, pressure, temperature, and supply position of the heating fluid, and the opening degree of the heating fluid injection port 2061 of the polishing surface heating section 206 when the polishing surface of the polishing pad 200 is heated by the polishing surface heating section 206, and at least one of the flow rate, pressure, temperature, and supply position of the cooling fluid, and the opening degree of the cooling fluid injection port 2071 of the polishing surface cooling section 207 when the polishing surface of the polishing pad 200 is cooled by the polishing surface cooling section 207.

The machine learning section 401 performs machine learning using a plurality of sets of learning data 11B. That is, the machine learning section 401 inputs a plurality of sets of learning data 11B to the learning model 10B, and generates a trained learning model 10B by causing the learning model 10B to learn the correlation between the substrate polishing information and the polishing surface temperature control information contained in the learning data 11B through supervised learning.

The learning model 10B employs, for example, a neural network structure, and includes an input layer 100, an intermediate layer 101, and an output layer 102. Synapses (not shown) that connect each neuron are laid between each layer, and each synapse is associated with a weight. A weight parameter group consisting of the weights of each synapse is adjusted by machine learning.

The input layer 100 has neurons whose number corresponds to the substrate polishing information as input data, and each value of the substrate polishing information is input to each neuron. The output layer 102 has neurons whose number corresponds to the polishing surface temperature control information as output data, and inference results of the polishing surface temperature control information for the substrate polishing information (inference results) are output as output data. When the learning model 10B is configured as a regression model, the polishing surface temperature control information is output as a numerical value normalized to a predetermined range (e.g., 0 to 1). When the learning model 10B is configured as a classification model, the polishing surface temperature control information is output as a score (accuracy) for each class as a numerical value normalized to a predetermined range (e.g., 0 to 1).

### Machine Learning Method

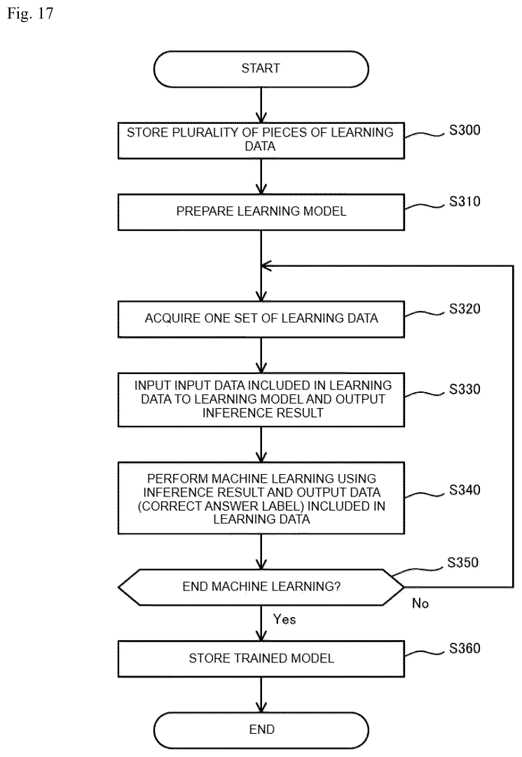

FIG. 17 is a flowchart showing an example of a machine learning method by the machine learning device 4a according to the second embodiment.

First, in step S300, the learning data acquisition section 400 acquires a desired number of pieces of learning data 11B as a preparatory step for starting machine learning, and stores the acquired learning data 11B in the learning data storage section 42.

Next, in step S310, the machine learning section 401 prepares a learning model 10B before learning in order to start machine learning. The learning model 10B before learning prepared here is configured as the neural network model exemplified in FIG. 16, and the weight of each synapse is set to an initial value.

Next, in step S320, the machine learning section 401 acquires, for example, one set of learning data 11B randomly from the plurality of sets of learning data 11B stored in the learning data storage section 42.

Next, in step S330, the machine learning section 401 inputs the substrate polishing information (input data) included in one set of learning data 11B to the input layer 100 of the prepared learning model 10B before learning (or during learning). As a result, the polishing surface temperature control information (output data) is output as an inference result from the output layer 102 of the learning model 10B, but the output data is generated by the learning model 10B before learning (or during learning). Therefore, in the state before learning (or during learning), the output data output as an inference result indicates information different from the polishing surface temperature control information (correct answer label) included in the learning data 11B.

Next, in step S340, the machine learning section 401 performs machine learning by comparing the polishing surface temperature control information (correct answer label) included in the set of learning data 11B acquired in step S320 with the polishing surface temperature control information (output data) output from the output layer as an inference result in step S330, and performing a process (backpropagation) to adjust the weight of each synapse. In this way, the machine learning section 401 causes the learning model 10B to learn the correlation between the substrate polishing information and the polishing surface temperature control information.

Next, in step S350, the machine learning section 401 determines whether a predetermined learning end condition has been satisfied based on, for example, an evaluation value of an error function based on the polishing surface temperature control information (correct answer label) included in the learning data 11B and the polishing surface temperature control information (output data) output as an inference result, or the remaining number of pieces of untrained learning data 11B stored in the learning data storage section 42.

In step S350, if the machine learning section 401 determines that the learning end condition is not satisfied and machine learning is to be continued (No in step S350), the process returns to step S320, and the process of steps S320 to S340 is performed a plurality of times on the learning model 10B being trained using untrained learning data 11B. On the other hand, in step S350, if the machine learning section 401 determines that the learning end condition is satisfied and machine learning is to be ended (Yes in step S350), the process proceeds to step S360.

Then, in step S360, the machine learning section 401 stores the trained learning model 10B (adjusted weight parameter group) generated by adjusting the weights associated with each synapse in the trained model storage section 43, and the series of machine learning methods shown in FIG. 17 ends. In the machine learning method, step S300 corresponds to a learning data acquisition process, steps S310 to S350 correspond to a machine learning process, and step S360 corresponds to a trained model storage process.

As described above, according to the machine learning device 4a and the machine learning method of the present embodiment, it is possible to provide the learning model 10B that generates the polishing surface temperature control information for the substrate polishing information. Therefore, since the temperature distribution of the polishing pad 200 is appropriately adjusted based on the polishing surface temperature control information generated by using the learning model 10B, the processing quality of the wafer W by the polishing process can be improved.

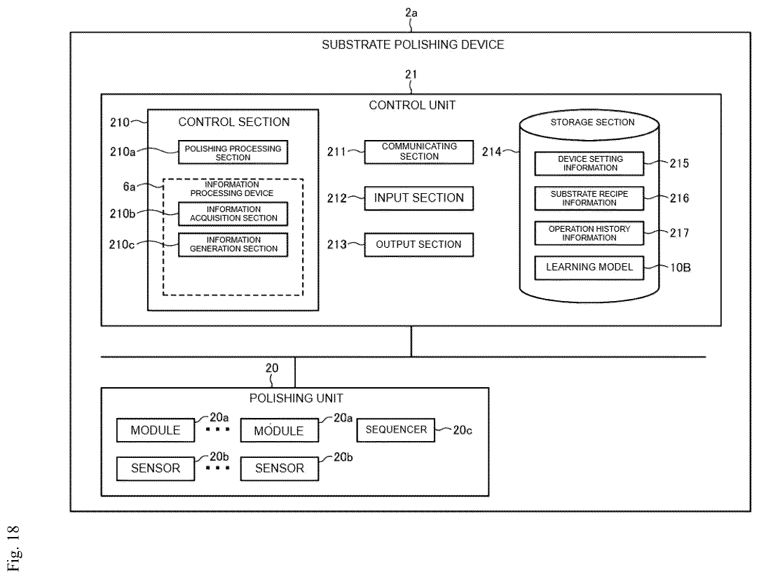

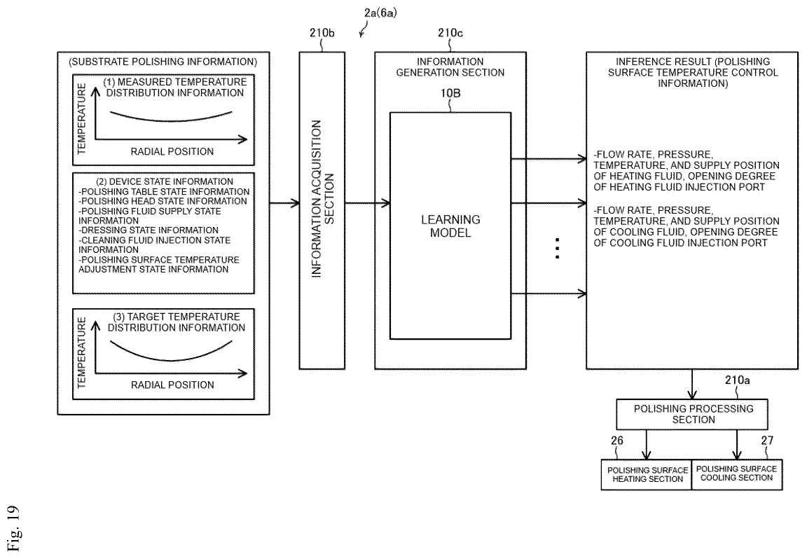

FIG. 18 is a block diagram showing an example of the substrate polishing device 2a (information processing device 6a) according to the second embodiment. FIG. 19 is a functional explanatory diagram showing an example of the substrate polishing device 2a (information processing device 6a) according to the second embodiment.

The control section 210 functions as the polishing processing section 210a, the information acquisition section 210b, and the information generation section 210c, and constitutes the information processing device 6a.

The information acquisition section 210b acquires the substrate polishing information including the measured temperature distribution information of the polishing pad 200 and the device state information of the substrate polishing device 2, as in the first embodiment. The substrate polishing information may include target temperature distribution information of the polishing pad 200 as shown in FIG. 18. Various pieces of data included in the substrate polishing information are the same as those in the first embodiment, and therefore will not be described.

The information generation section 210c inputs the substrate polishing information acquired by the information acquisition section 210b as input data to the learning model 10B, thereby generating polishing surface temperature control information when polishing process is performed by the substrate polishing device 2 having the device state indicated by the device state information included in the substrate polishing information on the polishing pad 200 having the temperature distribution indicated by the measured temperature distribution included in the substrate polishing information.

### Information Processing Method

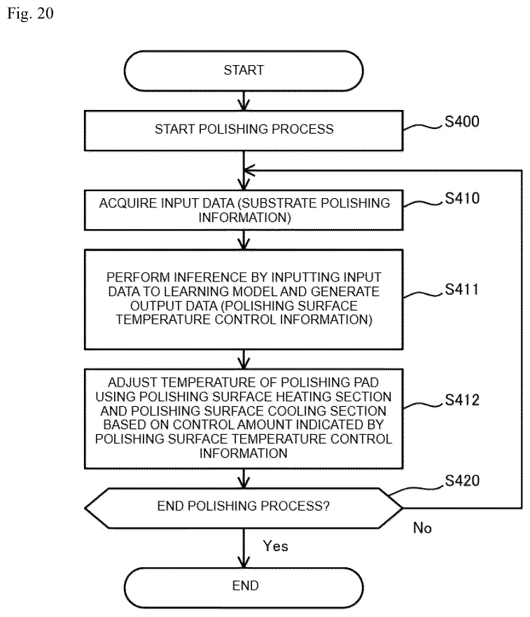

FIG. 20 is a flowchart showing an example of an information processing method by the substrate polishing device 2a (information processing device 6a) according to the second embodiment. An example of the operation when the substrate polishing device 2a performs polishing process on a specific wafer W will be described below.

First, in step S400, the polishing processing section 210a of the substrate polishing device 2 acquires detected values and measured values from the sensor group, and operates the module group in cooperation to start the polishing process for a specific wafer W.

Next, in step S410, the information acquisition section 210b acquires substrate polishing information at a specific time point.

Next, in step S411, the information generation section 210c generates polishing surface temperature control information by inputting the substrate polishing information acquired in step S410 as input data to the learning model 10A.

Next, in step S412, the polishing processing section 210a adjusts the temperature of the polishing pad 200 based on the control amount of the polishing surface heating section 206 and the polishing surface cooling section 207 indicated by the polishing surface temperature control information generated in step S411.

Next, in step S420, the polishing processing section 210a determines whether the polishing process has ended. As a result, if it is determined that the polishing process has not ended (No in step S420), the process returns to step S410 after the sampling time interval has elapsed, and the polishing process is continued. On the other hand, if it is determined that the polishing process has ended (Yes in step S420), the series of information processing methods shown in FIG. 20 ends. In the information processing method, steps S400 and S412 correspond to the polishing process step, step S410 corresponds to the information acquisition step, and step S411 corresponds to the information generation step.

As described above, according to the substrate polishing device 2a (information processing device 6a) and information processing method of this embodiment, by inputting the substrate polishing information to the learning model 10B, polishing surface temperature control information for the substrate polishing information is generated. Therefore, the temperature distribution of the polishing pad 200 is appropriately adjusted based on the polishing surface temperature control information, so that the processing quality of the wafer W by the polishing process can be improved.

### OTHER EMBODIMENTS

The disclosure is not limited to the above-mentioned embodiments, and various modifications can be made within the scope of the disclosure. All of these modifications are included in the technical concept of the disclosure.

In the above-mentioned embodiments, a case in which the information processing device 6, 6a is incorporated in the substrate polishing device 2, 2a has been described. Whereas, the information processing device 6, 6a may be configured as a device separate from the substrate polishing device 2, 2a, and may be configured as a general-purpose or dedicated computer 900, for example. In addition, the information processing device 6, 6a may be incorporated in the user terminal device 5, and the machine learning device 4, 4a may be incorporated in the user terminal device 5.

In the above-mentioned embodiments, the case where a neural network is adopted as a learning model for realizing machine learning by the machine learning section 401 is described, but other machine learning models may be adopted. Other machine learning models include, for example, tree-type models such as decision trees and regression trees, ensemble learning such as bagging and boosting, neural net models (including deep learning) such as recurrent neural networks, convolutional neural networks, and LSTMs, clustering models such as hierarchical clustering, non-hierarchical clustering, k-nearest neighbors, and k-means, multivariate analysis such as principal component analysis, factor analysis, and logistic regression, and support vector machines and the like.

### Machine Learning Program and Information Processing Program

The disclosure can also be provided in the form of a program (machine learning program) that causes the computer 900 to function as each part of the machine learning device 4, 4a, or a program (machine learning program) that causes the computer 900 to execute each step of the machine learning method. The disclosure can also be provided in the form of a program (information processing program) that causes the computer 900 to function as each part of the substrate polishing device 2, 2a, or a program (information processing program) that causes the computer 900 to execute each step of the information processing method according to the above embodiments.

### Inference Device, Inference Method, and Inference Program

The disclosure can be provided not only in the mode of the substrate polishing device 2, 2a (information processing method or information processing program) according to the above embodiment, but also in the mode of an inference device (inference method or inference program) used to infer polishing surface temperature control information. In this case, the inference device (inference method or inference program) can include a memory and a processor, and the processor executes a series of processes. The series of processes includes an information acquisition process (information acquisition step) for acquiring substrate polishing information, and an inference process (inference step) for inferring polishing surface temperature control information when a polishing process is performed by the substrate polishing device 2, 2a having the device state indicated by the device state information included in the substrate polishing information on the polishing surface having the temperature distribution indicated by the measured temperature distribution information included in the substrate polishing information when the substrate polishing information is acquired by the information acquisition process.

By providing in the mode of the inference device (inference method or inference program), it becomes easier to apply the invention to various devices compared to implementing an information processing device. It is naturally understood by those skilled in the art that when an inference device (inference method or inference program) infers polishing surface temperature control information, an inference method implemented by an information generation section may be applied using a trained learning model generated by the machine learning device and machine learning method according to the above embodiments.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. An information processing device comprising:
an information acquisition section that acquires substrate polishing information including measured temperature distribution information indicating a measured value of a temperature distribution of a polishing surface when a polishing process for polishing a substrate with the polishing surface of a polishing pad is performed by a substrate polishing device, and device state information indicating a device state of the substrate polishing device; and
an information generation section that inputs the substrate polishing information acquired by the information acquisition section into a learning model, thereby generating polishing surface temperature control information indicating a control amount of a polishing surface temperature adjustment section that adjusts the temperature distribution of the polishing surface when the polishing process is performed by the substrate polishing device having the device state indicated by the device state information included in the substrate polishing information for the polishing surface having the temperature distribution indicated by the measured temperature distribution information included in the substrate polishing information, wherein
the learning model is a trained model that has learned a correlation between the substrate polishing information and the polishing surface temperature control information by machine learning.

2. The information processing device according to claim 1, wherein
the device state information included in the substrate polishing information includes polishing surface temperature adjustment state information indicating a state of the polishing surface temperature adjustment section, and
the learning model is a trained model that has learned the correlation through reinforcement learning.

3. The information processing device according to claim 2, further comprising:
a machine learning section that calculates a reward based on a difference between target temperature distribution information indicating a target value of the temperature distribution of the polishing surface and the measured temperature distribution information when the polishing surface temperature adjustment section is controlled based on the control amount indicated by the polishing surface temperature control information generated by the information generation section, and causes the learning model to learn the correlation through reinforcement learning based on the reward.

4. The information processing device according to claim 1, wherein
the substrate polishing information includes target temperature distribution information indicating a target value of the temperature distribution of the polishing surface, and
the learning model is a trained model that has learned the correlation through supervised learning.

5. The information processing device according to claim 1, wherein
the measured temperature distribution information included in the substrate polishing information is a processed value obtained by performing normalization process on the measured values.

6. The information processing device according to claim 1, wherein
the device state information included in the substrate polishing information includes at least one of:
polishing table state information indicating a state of a polishing table section that rotatably supports the polishing pad;
polishing head state information indicating a state of a polishing head section that presses the substrate against the polishing pad;
polishing fluid supply state information indicating a state of a polishing fluid supply section that supplies polishing fluid to the polishing pad;
dressing state information indicating a state of a dressing section that performs dressing on the polishing pad;
cleaning fluid injection state information indicating a state of a cleaning fluid injection section that injects cleaning fluid onto the polishing pad; and
substrate state information indicating a state of the substrate.

7. The information processing device according to claim 6, wherein
the polishing table state information includes at least one of a rotation speed of the polishing table section, a rotation torque of the polishing table section, a type of the polishing pad, a surface roughness of the polishing pad, and a polishing time during which the polishing process is performed by the polishing pad,
the polishing head state information includes at least one of a rotation speed of the polishing head section, a rotation torque of the polishing head section, a polishing position of the polishing head section, and a pressing load of the polishing head section,
the polishing fluid supply state information includes at least one of a flow rate of the polishing fluid, a temperature of the polishing fluid, a dripping position of the polishing fluid, and a type of the polishing fluid,
the dressing state information includes at least one of a rotation speed of the dressing section, a rotation torque of the dressing section, a dressing position of the dressing section, a pressing load of the dressing section, a type of dressing pad of the dressing section, and a dressing time during which the dressing was performed by the dressing pad,
the cleaning fluid injection state information includes at least one of a flow rate of the cleaning fluid, a temperature of the cleaning fluid, a dripping position of the cleaning fluid, and a type of the cleaning fluid, and
the substrate state information includes at least one of a film thickness of the substrate, a film type of the substrate, and a temperature distribution of a surface of the substrate.

8. The information processing device according to claim 1, wherein
the polishing surface temperature control information includes at least one of at least one of a flow rate, pressure, temperature, and supply position of a heating fluid, and an opening degree of the heating fluid injection port for injecting the heating fluid when heating the polishing surface, and at least one of a flow rate, pressure, temperature, and supply position of the cooling fluid, and an opening degree of the cooling fluid injection port for injecting the cooling fluid when cooling the polishing surface.

9. A substrate polishing device comprising:
a polishing table section that rotatably supports a polishing pad;
a polishing head section that presses a substrate against a polishing surface of the polishing pad to polish the substrate;
a polishing fluid supply section that supplies a polishing fluid to the polishing pad;
a polishing surface temperature adjustment section that adjusts a temperature distribution of the polishing surface;
a polishing surface temperature measuring section that measures a temperature distribution of the polishing surface; and
a control section that controls a polishing process for polishing the substrate with the polishing surface, wherein
the control section includes:
an information acquisition section that acquires substrate polishing information including measured temperature distribution information indicating a measured value of the temperature distribution of the polishing surface measured by the polishing surface temperature measuring section and device state information indicating a device state of the substrate polishing device;
an information generation section that inputs the substrate polishing information acquired by the information acquisition section into a learning model, thereby generating polishing surface temperature control information indicating a control amount of the polishing surface temperature adjustment section when the polishing process is performed by the substrate polishing device having the device state indicated by the device state information included in the substrate polishing information on the polishing surface having the temperature distribution indicated by the measured temperature distribution information included in the substrate polishing information; and
a polishing processing section that controls the polishing surface temperature adjustment section based on the control amount indicated by the polishing surface temperature control information generated by the information generation section, and
the learning model is a trained model that has learned a correlation between the substrate polishing information and the polishing surface temperature control information by machine learning.

10. The substrate polishing device according to claim 9, wherein
the polishing surface temperature adjustment section includes at least one of:
one or more heating fluid injection ports for injecting a heating fluid onto the polishing surface to heat the polishing surface; and
one or more cooling fluid injection ports for injecting a cooling fluid onto the polishing surface to cool the polishing surface, and
the polishing surface temperature control information includes at least one of at least one of a flow rate, pressure, temperature, and supply position of the heating fluid, and an opening degree of the heating fluid injection port, and at least one of a flow rate, pressure, temperature, and supply position of the cooling fluid, and an opening degree of the cooling fluid injection port.

11. The substrate polishing device according to claim 9, wherein
the device state information included in the substrate polishing information includes polishing surface temperature adjustment state information indicating a state of the polishing surface temperature adjustment section,
the learning model is a trained model that has learned the correlation through reinforcement learning, and
the substrate polishing device includes a machine learning section that calculates a reward based on a difference between target temperature distribution information indicating a target value of the temperature distribution of the polishing surface and the measured temperature distribution information when the polishing surface temperature adjustment section is controlled based on the control amount indicated by the polishing surface temperature control information generated by the information generation section, and causes the learning model to learn the correlation through reinforcement learning based on the reward.

12. An inference device comprising a memory and a processor, the processor executing:
an information acquisition process for acquiring substrate polishing information including measured temperature distribution information indicating a measured value of a temperature distribution of a polishing surface when a polishing process for polishing a substrate with the polishing surface of a polishing pad is performed by a substrate polishing device, and device state information indicating a device state of the substrate polishing device, and
an inference process for inferring, upon acquiring the substrate polishing information by the information acquisition process, polishing surface temperature control information indicating a control amount of a polishing surface temperature adjustment section that adjusts the temperature distribution of the polishing surface when the polishing process is performed by the substrate polishing device having the device state indicated by the device state information included in the substrate polishing information for the polishing surface having the temperature distribution indicated by the measured temperature distribution information included in the substrate polishing information.

13. A machine learning device comprising:
a learning data acquisition section that acquires a plurality of sets of learning data composed at least of input data;
a machine learning section that uses the plurality of sets of learning data acquired by the learning data acquisition section to cause a learning model to learn a correlation between the input data and output data by machine learning; and
a trained model storage section that stores the learning model that has learned the correlation by the machine learning section, wherein
the input data is substrate polishing information including measured temperature distribution information indicating a measured value of a temperature distribution of the polishing surface when a polishing process for polishing a substrate with a polishing surface of a polishing pad is performed by a substrate polishing device, and device state information indicating a device state of the substrate polishing device, and
the output data is polishing surface temperature control information indicating a control amount of a polishing surface temperature adjustment section that adjusts the temperature distribution of the polishing surface when the polishing process is performed by the substrate polishing device.

14. The machine learning device according to claim 13, wherein
the learning data is composed of only the input data,
the device state information included in the substrate polishing information includes polishing surface temperature adjustment state information indicating a state of the polishing surface temperature adjustment section, and
the machine learning section causes the learning model to learn the correlation through reinforcement learning.

15. The machine learning device according to claim 13, wherein
the learning data is composed of the input data and the output data,
the substrate polishing information includes target temperature distribution information indicating a target value of the temperature distribution of the polishing surface, and
the machine learning section causes the learning model to learn the correlation through supervised learning.

16. An information processing method comprising:
an information acquisition step of acquiring substrate polishing information including measured temperature distribution information indicating a measured value of a temperature distribution of a polishing surface when a polishing process for polishing a substrate with the polishing surface of a polishing pad is performed by a substrate polishing device, and device state information indicating a device state of the substrate polishing device; and
an information generation step of inputting the substrate polishing information acquired by the information acquisition step into a learning model, thereby generating polishing surface temperature control information indicating a control amount of a polishing surface temperature adjustment section that adjusts the temperature distribution of the polishing surface when the polishing process is performed by the substrate polishing device having the device state indicated by the device state information included in the substrate polishing information for the polishing surface having the temperature distribution indicated by the measured temperature distribution information included in the substrate polishing information, wherein
the learning model is a trained model that has learned a correlation between the substrate polishing information and the polishing surface temperature control information by machine learning.

17. An inference method executed by an inference device comprising a memory and a processor, the processor executing:
an information acquisition process for acquiring substrate polishing information including measured temperature distribution information indicating a measured value of a temperature distribution of a polishing surface when a polishing process for polishing a substrate with the polishing surface of a polishing pad is performed by a substrate polishing device, and device state information indicating a device state of the substrate polishing device, and
an inference process for inferring, upon acquiring the substrate polishing information by the information acquisition process, polishing surface temperature control information indicating a control amount of a polishing surface temperature adjustment section that adjusts the temperature distribution of the polishing surface when the polishing process is performed by the substrate polishing device having the device state indicated by the device state information included in the substrate polishing information for the polishing surface having the temperature distribution indicated by the measured temperature distribution information included in the substrate polishing information.

18. A machine learning method executed by a computer, the method comprising:
a learning data acquisition step of acquiring a plurality of sets of learning data composed at least of input data;
a machine learning step of using the plurality of sets of learning data acquired by the learning data acquisition section to cause a learning model to learn a correlation between the input data and output data by machine learning; and
a trained model storage step of storing the learning model that has learned the correlation by the machine learning section, wherein
the input data is substrate polishing information including measured temperature distribution information indicating a measured value of a temperature distribution of the polishing surface when a polishing process for polishing a substrate with a polishing surface of a polishing pad is performed by a substrate polishing device, and device state information indicating a device state of the substrate polishing device, and
the output data is polishing surface temperature control information indicating a control amount of a polishing surface temperature adjustment section that adjusts the temperature distribution of the polishing surface when the polishing process is performed by the substrate polishing device.
